(19) United States
(12) Patent Application Publication
(10) Pub. No.: US 2025/0247054 A1
(43) Pub. Date: Jul. 31, 2025

(54) LOW NOISE AMPLIFIER USED AS A DUMMY LOAD AND REUSED AS A POST-AMPLIFIER TO AN EXTERNAL LOW NOISE AMPLIFIER

(71) Applicant: QUALCOMM Incorporated, San Diego, CA (US)

(72) Inventors: Bo QIAO, San Jose, CA (US); Arezou KHATIBI, Los Gatos, CA (US); Hongbing WU, Saratoga, CA (US); Sang Oh LEE, Cupertino, CA (US)

(21) Appl. No.: 18/814,331

(22) Filed: Aug. 23, 2024

Related U.S. Application Data
(60) Provisional application No. 63/627,337, filed on Jan. 31, 2024.

(51) Int. Cl. H03F 1/26; H03F 3/213

(52) U.S. Cl. CPC H03F 1/26; H03F 3/213; H03F 2200/09; H03F 2200/294

(57) ABSTRACT

A load inductor has first and second nodes. The first node couples to a first terminal of a first switch. A second terminal of the first switch couples to an output of a first low noise amplifier (LNA). The second node couples to a third terminal of a second switch. A fourth terminal of the second switch couples to an output of a second LNA. In response to receiving a single-ended signal at the first LNA, the first LNA is turned on, the first switch is closed, the second LNA is turned off, and the second switch is opened. In response to receiving the signal at the second LNA input, the first LNA is turned off, the first switch is opened, the second LNA is turned on, and the second switch is closed. The signal is transformed to a differential signal across the first and second inductor nodes.

### CROSS-REFERENCE TO RELATED APPLICATIONS

This application for patent claims priority to and the benefit of provisional patent application No. 63/627,337 entitled “Low Noise Amplifier Used as a Dummy Load and Reused as a Post-Amplifier to an External Low Noise Amplifier” filed in the United States Patent and Trademark Office on Jan. 31, 2024, the entire content of which is incorporated herein by reference as if fully set forth below in its entirety and for all applicable purposes.

### TECHNICAL FIELD

Aspects of the present disclosure generally relate to wireless communication user equipment and, more particularly, to one or more low noise amplifiers, each used as a dummy load and reused as a post-amplifier to an external low noise amplifier.

### INTRODUCTION

Manufacturers of wireless communication equipment, including mobile devices, handheld devices, and the subsystems therein, may find value in offering users various configurations and combinations of antennas and radio frequency front ends. In some situations, offering one product capable of being re-configured to operate in more than one configuration may be desirable. Scientists and engineers continuously search for ways to manufacture one subsystem that may be used for at least two alternative configurations.

### BRIEF SUMMARY OF SOME EXAMPLES

The following presents a simplified summary of one or more implementations in order to provide a basic understanding of such implementations. This summary is not an extensive overview of all contemplated implementations. It is intended to neither identify key or critical elements of all implementations nor delineate the scope of any or all implementations. Its sole purpose is to present some concepts of one or more implementations in a simplified form as a prelude to the more detailed description presented later.

In one example, an apparatus is described. The apparatus includes a load inductor having a first inductor node at a first end, a second inductor node at a second end, and a center inductor node between the first end and the second end. The apparatus includes a first switch having a first terminal and a selectively opened or closed second terminal, the first terminal coupled to the first inductor node. The apparatus includes a second switch having a third terminal and a selectively opened or closed fourth terminal, the third terminal coupled to the second inductor node. The apparatus includes a first low noise amplifier (LNA) having a first LNA input and a first LNA output, the first LNA output coupled to the selectively opened or closed second terminal of the first switch. The apparatus includes a second LNA having a second LNA input and a second LNA output, the second LNA output coupled to the selectively opened or closed fourth terminal of the second switch.

In another example, a method at an apparatus is described. The method includes receiving a single-ended signal at either a first low noise amplifier input of a first LNA or a second LNA input of a second LNA. The method next either turns on the first LNA, closes a first switch coupling a first LNA output of the first LNA to a first inductor node of a load inductor, turns off the second LNA, and opens a second switch coupling a second LNA output of the second LNA to a second inductor node of the load inductor in response to the receiving the single-ended signal at the first LNA input, or turns off the first LNA, opens the first switch, turns on the second LNA, and closes the second switch, in response to the receiving the single-ended signal at the second LNA input. The method also includes transforming the received single-ended signal to an amplified differential output signal across the first inductor node and the second inductor node.

In an additional example, an apparatus that includes one or more memories and one or more processors is described. The one or more processors are configured to, individually or collectively, based at least in part on information stored in the one or more memories, receive a single-ended signal at either a first low noise amplifier input of a first LNA or a second LNA input of a second LNA. The one or more processors are also configured to either turn on the first LNA, close a first switch coupling a first LNA output of the first LNA to a first inductor node of a load inductor, turn off the second LNA, and open a second switch coupling a second LNA output of the second LNA to a second inductor node of the load inductor in response to the receiving the single-ended signal at the first LNA input, or are configured to turn off the first LNA, open the first switch, turn on the second LNA, and close the second switch, in response to the receiving the single-ended signal at the second LNA input. The one or more processors are further configured to transform the received single-ended signal to an amplified differential output signal across the first inductor node and the second inductor node.

In another example, another apparatus is described. The apparatus includes means for receiving a single-ended signal at either a first low noise amplifier input of a first LNA or a second LNA input of a second LNA. The apparatus includes means for either turning on the first LNA, closing a first switch coupling a first LNA output of the first LNA to a first inductor node of a load inductor, turning off the second LNA, and opening a second switch coupling a second LNA output of the second LNA to a second inductor node of the load inductor in response to the receiving the single-ended signal at the first LNA input, or means for turning off the first LNA, opening the first switch, turning on the second LNA, and closing the second switch, in response to the receiving the single-ended signal at the second LNA input. The apparatus further includes means for transforming the received single-ended signal to an amplified differential output signal across the first inductor node and the second inductor node.

In another example, a non-transitory computer-readable medium storing instructions is described. In the example, the instructions may be executed by a processing circuit having one or more processors. In the example, in response to the instructions being executed by the processing circuit having one or more processors, the instructions cause the one or more processors, individually or collectively, to receive a single-ended signal at either a first low noise amplifier input of a first LNA, or a second LNA input of a second LNA. The instructions also cause the one or more processors, individually or collectively, to either turn on the first LNA, close a first switch coupling a first LNA output of the first LNA to a first inductor node of a load inductor, turn off the second LNA, and open a second switch coupling a second LNA output of the second LNA to a second inductor node of the load inductor in response to the receiving the single-ended signal at the first LNA input, or turn off the first LNA, open the first switch, turn on the second LNA, and close the second switch, in response to the receiving the single-ended signal at the second LNA input. The instructions also cause the one or more processors, individually or collectively, to transform the received single-ended signal to an amplified differential output signal across the first inductor node and the second inductor node.

To accomplish the foregoing and related ends, the one or more implementations include the features hereinafter fully described and particularly pointed out in the claims. The following description and the appended drawings set forth in detail certain illustrative aspects of the one or more implementations. These aspects are indicative, however, of but a few of the various ways in which the principles of various implementations may be employed, and the descriptions of the various implementations are intended to include all such aspects and their equivalents. The relative dimensions of the following figures may not be drawn to scale.

### BRIEF DESCRIPTION OF THE DRAWINGS

FIG. 1 is a schematic illustration of an example wireless communication system according to some aspects of the disclosure.

FIGS. 2A and 2B are simplified block diagrams of two radio frequency front ends (RFFEs) according to some aspects of the disclosure.

FIGS. 3A, 3B, and 3C are simplified block diagrams of two external equipment configurations associated with two RFFEs according to some aspects of the disclosure.

FIGS. 4A and 4B are simplified bock diagrams and schematics of an internal low noise amplifier (LNA) core according to some aspects of the disclosure.

FIG. 5 is a schematic drawing of an RFFE operable in an internal LNA configuration or an external LNA configuration according to some aspects of the disclosure.

FIG. 6 is a schematic representation of an LNA core according to some aspects of the disclosure.

FIG. 7 is a block diagram illustrating an example of a hardware implementation of an apparatus employing one or more processing systems according to some aspects of the disclosure.

FIG. 8 is a flow chart illustrating an example process at an apparatus according to some aspects of the disclosure.

Like reference numbers and designations in the various drawings indicate like elements.

### DETAILED DESCRIPTION

The detailed description set forth below in connection with the appended drawings is directed to some particular examples for the purpose of describing innovative aspects of this disclosure. However, a person having ordinary skill in the art will readily recognize that the teachings herein can be applied in a multitude of different ways. Some or all of the described examples may be implemented in any device, system, or network that is capable of transmitting and receiving radio frequency (RF) signals according to one or more of the Institute of Electrical and Electronics Engineers (IEEE) 802.11 (WiFi®) standards, the IEEE 802.15 standards, the Bluetooth® standards as defined by the Bluetooth Special Interest Group (SIG), or the Long Term Evolution (LTE), 3G, 4G or 5G (New Radio (NR)) standards promulgated by the 3rd Generation Partnership Project (3GPP), among others. The described examples can be implemented in any device, system, or network that is capable of transmitting and receiving RF signals according to one or more of the following technologies or techniques: code division multiple access (CDMA), time division multiple access (TDMA), frequency division multiple access (FDMA), orthogonal FDMA (OFDMA), single-carrier FDMA (SC-FDMA), spatial division multiple access (SDMA), rate-splitting multiple access (RSMA), multi-user shared access (MUSA), single-user (SU) multiple-input multiple-output (MIMO) and multi-user (MU)-MIMO. The described examples also can be implemented using other wireless communication protocols or RF signals suitable for use in one or more of a wireless personal area network (WPAN), a wireless local area network (WLAN), a wireless wide area network (WWAN), a wireless metropolitan area network (WMAN), or an internet of things (IoT) network.

The detailed description set forth below, in connection with the appended drawings, is intended as a description of various configurations and is not intended to represent the only configurations in which the concepts described herein may be practiced. The detailed description includes specific details to provide a thorough understanding of the various concepts. However, it will be apparent to persons having ordinary skill in the art that these concepts may be practiced without these specific details. In some instances, well-known structures and components are shown in block diagram form in order to avoid obscuring such concepts.

While aspects and examples are described in this application by illustration to some examples, persons having ordinary skill in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range a spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for the implementation and practice of claimed and described examples. For example, transmission and reception of wireless signals necessarily includes a number of components for analog and digital purposes (e.g., hardware components including antenna, RF-chains, power amplifiers, modulators, buffer, processor(s), interleaver, adders/summers, etc.). It is intended that innovations described herein may be practiced in a wide variety of devices, chip-level components, systems, distributed arrangements, disaggregated arrangements (e.g., base station and/or user equipment (UE)), end-user devices, etc. of varying sizes, shapes, and constitution.

Described herein are hardware and methods associated with wireless communication devices (e.g., apparatus, scheduled entities, mobile devices) that may utilize various configurations of interfaces between one or more wireless communication device antennas and an radio frequency front end (RFFE) of a respective wireless communication device. The RFFE includes, among other things, a low noise amplifier(s), a power amplifier(s), and various switches. In one configuration known as an “internal low noise amplifier” (iLNA) configuration or mode, the wireless communication device utilizes an internal low noise amplifier and may not utilize an LNA that is external to the RFFE. In another example, known as an “external low noise amplifier” (xLNA) configuration or mode, the wireless communication device utilizes an LNA that is external to the RFFE and may also use an external antenna multiplexer switch.

Described herein are methods and apparatus that facilitate the manufacture and use of one RFFE configured to operate according to either the iLNA configuration or the xLNA configuration. In the examples described herein, in the iLNA configuration, a first internal LNA serves as a first amplification stage (i.e., the first LNA stage) in a receiver chain, while a second iLNA (fabricated in the same internal LNA core as the first LNA) serves as a dummy load to a single-ended to differential transformer. In the xLNA configuration, the second LNA serves as a post-amplification stage (i.e., a stage of amplification following the first amplification stage performed by an external LNA 244) in a receiver chain, while the first LNA serves as the dummy load.

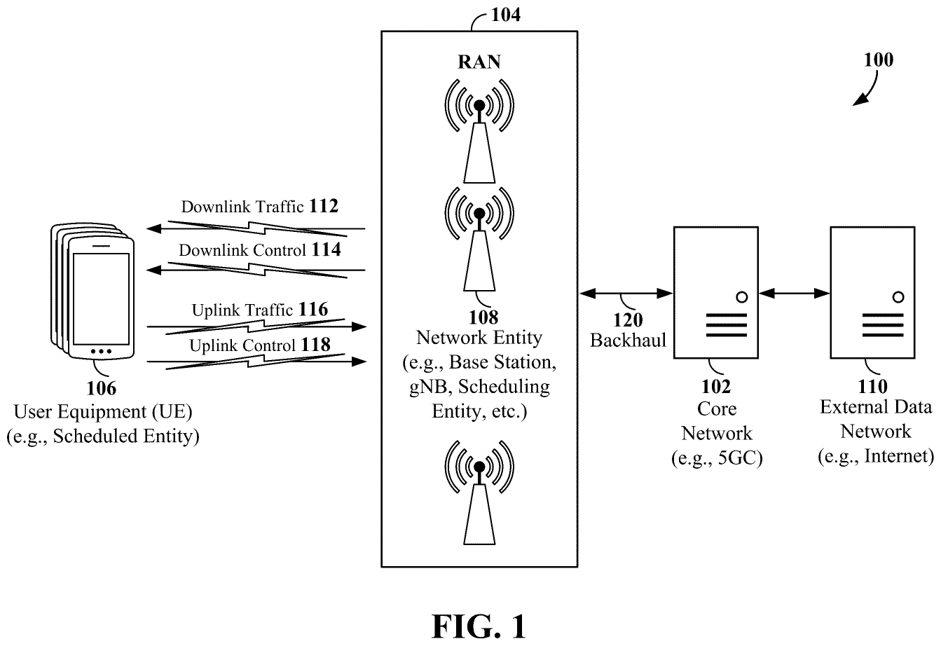

FIG. 1 is a schematic illustration of an example of a wireless communication system 100 according to some aspects of the disclosure. The wireless communication system 100 includes three interacting domains: a core network 102, a radio access network (RAN) 104, and a user equipment (UE) 106. By virtue of the wireless communication system 100, the UE 106 (also referred to herein as a wireless communication device or an apparatus) may be enabled to carry out data communication with an external data network 110, such as (but not limited to) the Internet. The UE 106 may include a transceiver having an RFFE module (not shown to avoid cluttering the drawing) such as those described herein in accordance with various aspects of the disclosure.

The RAN 104 may implement any suitable wireless communication technology or technologies to provide radio access to the UE 106. As one example, the RAN 104 may operate according to the European telecommunications standards institute (ETSI) global system for mobile communications (GSM) specifications. As another example, the RAN 104 may operate according to 3rd Generation Partnership Project (3GPP) New Radio (NR) specifications, often referred to as 5G. As a further example, the RAN 104 may operate under a hybrid of 5G NR and Evolved Universal Terrestrial Radio Access Network (eUTRAN) standards, often referred to as Long-Term Evolution (LTE). The 3GPP refers to this hybrid RAN as a next-generation RAN, or NG-RAN. In another example, the RAN 104 may operate according to both the LTE and 5G NR standards. Of course, many other examples may be utilized within the scope of the present disclosure.

As illustrated, the RAN 104 includes a plurality of network entities 108. Broadly, a network entity may be implemented in an aggregated or monolithic base station architecture, or in a disaggregated base station architecture, and may include one or more of a central unit (CU), a distributed unit (DU), a radio unit (RU), a Near-Real Time (Near-RT) RAN Intelligent Controller (RIC), or a Non-Real Time (Non-RT) RIC. In some examples, a network entity may be a network element in a radio access network responsible for radio transmission and reception in one or more cells to or from a UE. In different technologies, standards, or contexts, a network entity may variously be referred to by persons having ordinary skill in the art as a base transceiver station (BTS), a radio base station, a base station, a radio transceiver, a transceiver function, a basic service set (BSS), an extended service set (ESS), an access point (AP), a Node B (NB), an eNode B (eNB), a gNode B (gNB), a transmission and reception point (TRP), a scheduling entity, a network entity, or some other suitable terminology. In some examples, a network entity may include two or more TRPs that may be collocated or non-collocated. Each TRP may communicate on the same or different carrier frequency within the same or different frequency band. In examples where the RAN 104 operates according to both the LTE and 5G NR standards, one of the network entities may be an LTE network entity, while another network entity may be a 5G NR network entity.

The RAN 104 is further illustrated supporting wireless communication for multiple mobile apparatuses. A mobile apparatus may be referred to as user equipment (UE) in 3GPP standards, but may also be referred to by persons having ordinary skill in the art as a mobile station (MS), a subscriber station, a mobile unit, a subscriber unit, a wireless unit, a remote unit, a mobile device, a wireless device, a wireless communication device, a remote device, a mobile subscriber station, an access terminal (AT), a mobile terminal, a wireless terminal, a remote terminal, a handset, a terminal, a user agent, a mobile client, a client, a scheduled entity, or some other suitable terminology. A UE 106 may be an apparatus (e.g., a scheduled entity, a user equipment, a wireless communications device, a mobile communication device) that provides a user with access to network services.

The terms UE, scheduled entity, mobile apparatus, apparatus, and mobile device broadly refer to a diverse array of devices and technologies. Within the present disclosure, a “mobile” apparatus need not necessarily have a capability to move and may be stationary. UEs may include a number of hardware structural components sized, shaped, and arranged to help in communication; such components can include antennas, antenna arrays, RF front-ends, RF chains, amplifiers, one or more processors, etc., electrically coupled to each other. For example, some non-limiting examples of a mobile apparatus include a mobile, a cellular (cell) phone, a smart phone, a session initiation protocol (SIP) phone, a laptop, a personal computer (PC), a notebook, a netbook, a smartbook, a tablet, a personal digital assistant (PDA), and a broad array of embedded systems, e.g., corresponding to an Internet of Things (IoT).

A UE may additionally be incorporated into or include an automotive or another type of transportation vehicle, a remote sensor or actuator, a robot or robotics device, a satellite radio, a global positioning system (GPS) device, an object tracking device, a drone, a multi-copter, a quad-copter, a remote control device, a consumer and/or wearable device, such as eyewear, a wearable camera, a virtual reality device, a smart watch, a health or fitness tracker, a digital audio player (e.g., MP3 player), a camera, a game console, etc. A UE may additionally be a digital home or smart home device such as a home audio, video, and/or multimedia device, an appliance, a vending machine, intelligent lighting, a home security system, a smart meter, etc. A UE may additionally be a smart energy device, a security device, a solar panel or solar array, a municipal infrastructure device controlling electric power (e.g., a smart grid), lighting, water, etc., an industrial automation and enterprise device, a logistics controller, agricultural equipment, etc. Still further, a UE may provide connected medicine or telemedicine support, i.e., health care at a distance. Telehealth devices may include telehealth monitoring devices and telehealth administration devices, whose communication may be given preferential treatment or prioritized access over other types of information, e.g., in terms of prioritized access for transport of critical service data and/or relevant QoS for transport of critical service data.

Wireless communication between the RAN 104 and the UE 106 may be described as utilizing an air interface. Transmissions over the air interface from a base station (e.g., base station 108) to one or more UEs (e.g., similar to UE 106) may be referred to as downlink (DL) transmission. In accordance with certain aspects of the present disclosure, the term downlink may refer to a point-to-multipoint transmission (e.g., a groupcast, a multicast) or a point-to-point transmission (e.g., a unicast) originating at a network entity (e.g., a base station, similar to network entity 108). Another way to describe this scheme may be to use the term broadcast channel multiplexing. Transmissions from a UE (e.g., UE 106) to a network entity (e.g., network entity 108) may be referred to as uplink (UL) transmissions. In accordance with further aspects of the present disclosure, the term uplink may refer to a point-to-point transmission originating at a UE (e.g., UE 106).

In some examples, access to the air interface may be scheduled, where a network entity (e.g., similar to network entity 108) allocates resources for communication among some or all devices and equipment within its service area or cell. Within the present disclosure, as discussed further below, the network entity may be responsible for scheduling, assigning, reconfiguring, and releasing resources for one or more scheduled entities (e.g., UEs 106). That is, for scheduled communication, a plurality of UEs 106, which may be scheduled entities, may utilize resources allocated by the network entity 108.

Network entities 108 are not the only entities that may function as scheduling entities. In some examples, a UE may function as a scheduling entity, scheduling resources for one or more scheduled entities (e.g., one or more other UEs). For example, UEs may communicate with other UEs in a peer-to-peer or device-to-device fashion and/or in a relay configuration.

As illustrated in FIG. 1, the network entity 108 may broadcast downlink traffic 112 (also referred to as downlink data traffic) to one or more UEs 106. Broadly, the network entity 108 may be a node or device responsible for scheduling traffic (e.g., data traffic, user data traffic) and scheduling control (e.g., control information) in a wireless communication network, including the downlink traffic 112 and/or downlink control 114 and, in some examples, uplink traffic 116 and/or uplink control 118 from one or more scheduled entities to the scheduling entity. On the other hand, the UE 106 (e.g., the scheduled entity) may be a node or device that receives downlink traffic 112 and downlink control 114, including but not limited to scheduling information (e.g., a grant), synchronization or timing information, or other control information from another entity in the wireless communication network such as the network entity 108. The UE 106 may further transmit uplink control 118 information, including but not limited to a scheduling request, feedback information, or other control information, to the network entity 108.

The uplink control 118 information, downlink control 114 information, downlink traffic 112, and/or uplink traffic 116 may transmitted on a waveform that may be time-divided into frames, subframes, slots, and/or symbols. As used herein, a symbol may refer to a unit of time that, in an orthogonal frequency division multiplexed (OFDM) waveform, carries one resource element (RE) per sub-carrier. A slot may carry a certain number of OFDM symbols (e.g., 7 or 14 OFDM symbols) in some examples. A subframe may refer to a specified duration (e.g., one millisecond (ms)). Multiple subframes or slots may be grouped together to form a single frame or radio frame. Within the present disclosure, a frame may refer to a predetermined duration (e.g., 10 ms) for wireless transmissions, with each frame consisting of, for example, 10 subframes of 1 ms each. Of course, these definitions are not required; any suitable scheme for organizing waveforms may be utilized, and various time divisions of the waveform may have any suitable duration.

In general, each network entity 108 may include a backhaul interface (not shown) for communication with a backhaul portion 120 of the wireless communication system. The backhaul portion 120 may provide a link between a network entity 108 and the core network 102. Further, in some examples, a backhaul network may provide interconnection between respective network entities 108. Various types of backhaul interfaces may be employed, such as a direct physical connection, a virtual network, or the like, using any suitable transport network.

The core network 102 may be a part of the wireless communication system 100 and may be independent of the radio access technology used in the RAN 104. In some examples, the core network 102 may be configured according to ETSI standards, 5G standards (e.g., 5G core (5GC)), or according to other 3GPP standards such as a 4G evolved packet core (EPC) or any other suitable standard or configuration.

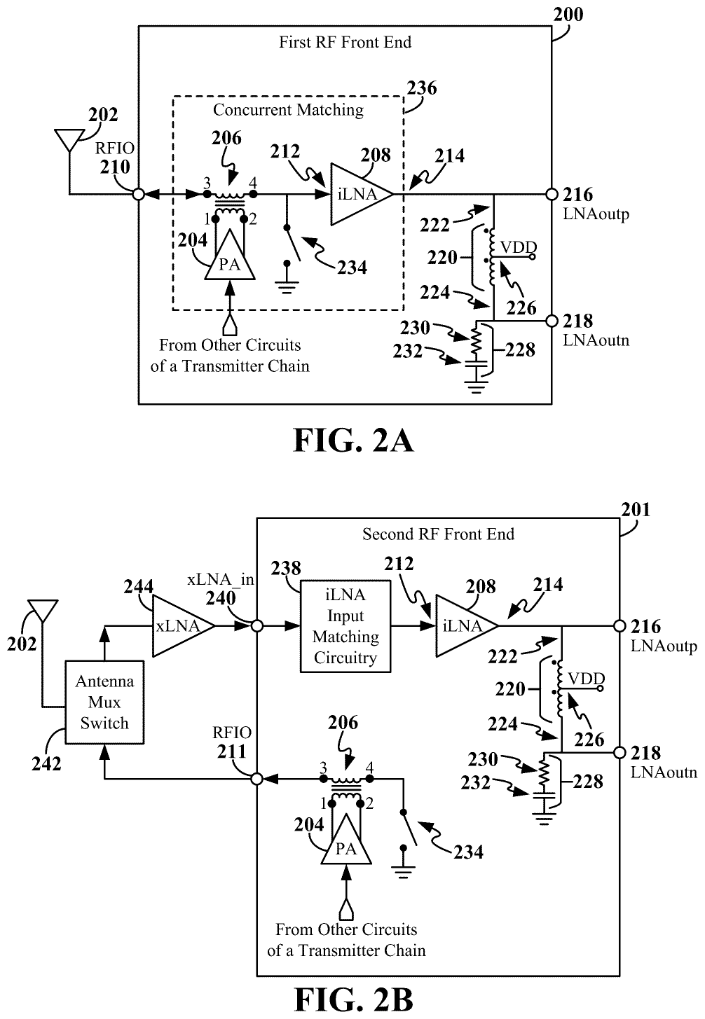

FIGS. 2A and 2B are simplified block diagrams of two radio frequency front end (RFFEs) 200 according to some aspects of the disclosure. The first RFFE 200 is depicted with an antenna 202; however, the antenna 202 may be an antenna array. The antenna or antenna array is generally represented herein by the antenna 202 for case of illustration. In the example of FIG. 2A, the antenna 202 transmits and receives traffic and control signals, such as the uplink traffic 116, uplink control 118, and downlink traffic 112, downlink control 114, as shown and described in connection with FIG. 1. The antenna 202 couples to a first RF input/output (RFIO) port 210 of the first RFFE 200.

The first RFFE 200 includes a power amplifier 204 and a power amplifier balun 206. Circuits in the transmitter chain (not shown) associated with the power amplifier 204 provide the power amplifier 204 with signals to be amplified and transmitted via the antenna 202.

The power amplifier balun 206 has four terminals labeled 1, 2, 3, 4. The power amplifier balun 206 may be a transformer that transforms a differential output (also referred to as balanced output) of the power amplifier 204 to a single-ended output (also referred to as unbalanced output). The differential output of the power amplifier 204 is presented across terminals 1 and 2 of the power amplifier balun 206. The single-ended output is presented at terminal 3 of the power amplifier balun 206. Of course, the preceding description is non-limiting. The transmitter chain that includes the power amplifier 204 and power amplifier balun 206 may include other circuits as known to persons having ordinary skill in the art.

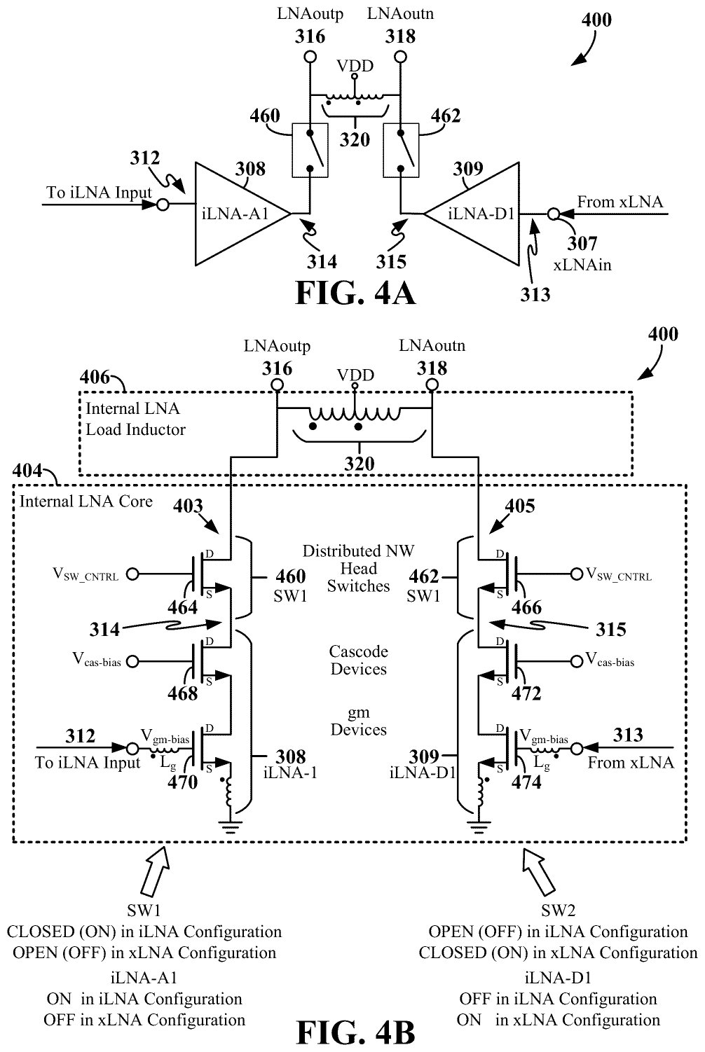

The first RFFE 200 also includes an internal low noise amplifier (iLNA) 208. The iLNA 208 may be fabricated on an internal low noise amplifier core, similar to the internal low noise amplifier core 404, as shown and described in connection with FIG. 4 below. A through path between the antenna 202 and an LNA input 212 is provided between terminals 3 and 4 of the power amplifier balun 206. In the example of FIG. 2A, and other examples described herein, the LNA input 212 and an LNA output 214 are single-ended (but are not limited to such a configuration).

Between, and in parallel with, the power amplifier balun 206 and the LNA input 212 is an internal transmit/receive switch 234 (where the term “transmit/receive” may mean “transmit or receive” herein). In some examples, the internal transmit/receive switch 234 may be implemented using a diode or a transistor. In the example of FIG. 2A, the internal transmit/receive switch 234 is configured as a single-pole-single-throw (SPST) switch. Other configurations of switches are within the scope of the disclosure.

For consistency and ease of illustration, all switches exemplified herein will be described as being in either an “open” state or a “closed” state. The internal transmit/receive switch 234 presents a high impedance between its input and output terminals in the open state. The internal transmit/receive switch 234, which is in a shunt configuration in FIG. 2A and FIG. 2B presents a low impedance between its input and output terminals in the closed state. The open state may correspond to a diode or transistor switch in an “off” state. The closed state may correspond to a diode or transistor switch in an “on” state.

For example, in a case where the internal transmit/receive switch 234 is implemented using a p-n junction diode, the switch may be said to be in the open state (corresponding to the “off” state) in response to the p-n junction of the diode being reverse biased (where current is impeded from passing through the diode). The switch may be said to be in the closed state (corresponding to the “on” state) in response to the p-n junction of the diode being forward biased (where current is not impeded from passing through the diode). In a case where the internal transmit/receive switch 234 is implemented using an n-channel metal-oxide semiconductor (NMOS) transistor, for example, the switch may be said to be in the open state (corresponding to the off state) in response to operating the NMOS transistor in its cut-off region (where the channel is closed in response to the input gate voltage=0 V, drain current=0 A, and drain-source voltage (VDS)=drain supply voltage (VDD)); and the switch may be said to be in the closed state (corresponding to the on state) in response to operating the NMOS transistor in its linear region (where the channel resistance is as small as possible with a maximum amount of drain current flowing through the switch in response to the gate voltage being tied to VDD or a value greater than VDD).

The internal transmit/receive switch 234 may be referred to as the internal transmit/receive switch because it is integrated with other components on the chip that includes the internal LNA core, and is associated with the transmit and receive states of the first RFFE 200. For example, in operation, the internal transmit/receive switch 234 is in the closed state during signal transmission via the power amplifier 204. Being in the closed state protects the iLNA 208 from the relatively high power at the output of the power amplifier 204. The internal transmit/receive switch 234 is in the open state during signal reception via the iLNA 208. In the open state, the internal transmit/receive switch 234 is relatively transparent to the iLNA 208.

The impedances of the power amplifier 204, the power amplifier balun 206, the internal transmit/receive switch 234, and the iLNA 208 may be optimized utilizing concurrent matching 236 (represented by a dashed box surrounding the recited components in FIG. 2A). Utilizing concurrent matching, the just recited components are simultaneously optimized to achieve a desired input impedance, as seen at the first RFIO port 210 of FIG. 2A, for example. A goal for the desired input impedance may be 50 Ohms with zero reactance; however, those having ordinary skill in the art will recognize that over an operating bandwidth of the system, some variation in the resistive portion of the impedance and some variation and non-zero values of the reactance portion of the impedance are within the scope of the disclosure.

The LNA output 214 is single-ended and is converted to a differential output across the LNAoutp 216 and LNAoutn 218 terminals of an internal LNA load inductor 220 (also referred to herein as an inductor or a load inductor). The internal LNA load inductor 220 has a first inductor node 222 at a first end and a second inductor node 224 at a second end. The internal LNA load inductor 220 also has a center inductor node 226 between the first and second ends. The center inductor node 226 may be formed as a tap (as in a tap of a transformer coil) at the center of the internal LNA load inductor 220 between the first and second end of the inductor. Here, the term “center” does not imply absolute precision. The internal LNA load inductor 220 may not be symmetrical. The internal LNA load inductor 220 may be formed of a known length of conductive material (e.g., gold, copper), where, for example, the inductor may be formed of conductive traces on multiple layers of a circuit board with conductive vias between the multiple layers. A first length of the conductive material between the first end of the internal LNA load inductor 220 and the center inductor node 226 may be more than, equal to, or less than a second length of the conductive material between the second end of the internal LNA load inductor 220 and the center inductor node 226. Accordingly, the LNAout signal may not be perfectly balanced; however, the LNAout signal may be considered a differential signal because the circuit that includes the internal LNA load inductor 220 may have a common-mode gain that is more than 30 dB lower than the differential gain of the circuit.

In the example of FIG. 2A, the winding of the internal LNA load inductor 220, from the first inductor node 222 to the second inductor node 224, may be a continuous construction. In a case where the internal LNA load inductor 220 is a printed circuit inductor, the presence of vias and bridges (not shown) coupling segments of the internal LNA load inductor 220 to one another is considered part of a continuous construction.

As shown by the use of the dot convention in the drawings herein (including FIGS. 2A and 2B) and based on the winding of the internal LNA load inductor 220, a polarity of the first inductor node 222 relative to the center inductor node 226 is opposite to the polarity of the second inductor node 224 relative to the center inductor node 226. Accordingly, because the first inductor node 222 and the LNAoutp 216 terminal may be considered as one electrical node, and as the second inductor node 224 and the LNAoutn 218 terminal may be considered as one electrical node, the LNAoutp 216 terminal may be described as a positive terminal, and the LNAoutn 218 terminal may be described as a negative terminal. The internal LNA load inductor 220 with the center inductor node 226 (also referred to as a center tap) may serve as a transformer, transforming the single-ended LNA output 214 to a differential output across the positive and negative terminals, LNAoutp 216 and LNAoutn 218 terminals, respectively.

Also included in the first RFFE 200 is a first load 228 that terminates the second inductor node 224 (and the LNAoutn 218 terminal). The first load 228 may be referred to as a “dummy load.” In some examples, the first load 228 may be used to match the internal LNA load inductor 220 impedances at the single-ended input to the differential output. Matching the impedances may minimize signal reflections. In another example, the first load 228 may absorb at least some reflections that may be seen at the second inductor node 224. In the example of FIG. 2A, the first load 228 is depicted as a lumped element series combination of a resistor 230 and a capacitor 232. The series combination of the resistor 230 and capacitor 232 is illustrated for discussion purposes and not limitation.

In some examples, the dummy load may be replaced with a second LNA (not shown) (e.g., similar to, or a duplicate of, the iLNA 208). In some examples, the second LNA (not shown) may be utilized to introduce an output of an external LNA (e.g., similar to the xLNA 244 of FIG. 2B) to the existing receiver chain after low noise amplification by the external LNA. Such an example may be implemented with minimal performance degradation and minimal design overhead.

In some examples, a high impedance switch (not shown) may be configured in series between, for example, an LNA output network and each of the iLNA 208 and the second LNA. In operation, either the iLNA 208 or the second LNA would be in an on state, while the other was in an off state. The high impedance switch may isolate an LNA's parasitic capacitance in an off state from the LNA output network.

FIG. 2B is a simplified block diagram of a second RFFE 201 according to some aspects of the disclosure. Like reference numbers in FIG. 2A and 2B correspond to like elements. To avoid redundancy, the description of the like elements provided with FIG. 2A will not be repeated in the description of FIG. 2B.

The second RFFE 201 includes a second RFIO port 211, similar to the first RFIO port 210 of FIG. 2A but associated with a different configuration of components. Notably, the first RFIO port 210 of FIG. 2A is used for input and output (IO), while the second RFIO port 211 of FIG. 2B is used for output only (despite retaining the letters “IO” in its name). The second RFFE 201 includes the LNAoutp 216 terminal (e.g., positive LNA output terminal) and the LNAoutn 218 terminal (e.g., negative LNA output terminal) similar to those of FIG. 2A.

The second RFFE 201 includes a power amplifier 204, a power amplifier balun 206, and an internal transmit/receive switch 234. The second RFFE 201 includes an iLNA 208 having an LNA input 212 and the LNA output 214. In contrast to the concurrent matching 236 utilized in the first RFFE 200 of FIG. 2A, the iLNA 208 of FIG. 2B may utilize iLNA input matching circuitry 238.

The second RFFE 201 includes an internal LNA load inductor 220 (having a first inductor node 222, a second inductor node 224, and a center inductor node 226). The first inductor node 222 is coupled to the LNA output 214 and the LNAoutp 216 terminal. The second inductor node 224 is coupled to the LNAoutn 218 terminal and a first load 228 (illustrated, for discussion purposes and not limitation, as a series combination of the lumped element resistor 230 and capacitor 232).

In contrast to FIG. 2A, where the LNA input 212 is coupled to the power amplifier balun 206 (at terminal 4 of the power amplifier balun 206) and the internal transmit/receive switch 234, the LNA input 212 of FIG. 2B is coupled to an output of the iLNA input matching circuitry 238. The input of the iLNA input matching circuitry 238 is coupled to an “external LNA in” port (the “xLNA_in port 240”). Accordingly, while the first RFFE 200 of FIG. 2A has one RFIO port, namely, the first RFIO port 210, dedicated to both RF reception and transmission, the second RFFE 201 of FIG. 2B has a first port (i.e., the xLNA_in port 240) dedicated to RF reception and a second port (i.e., the second RFIO port 211) dedicated to RF transmission.

In instances where the second RFFE 201 is utilized with two antennas (not shown) (e.g., where a first antenna is coupled to the xLNA_in port 240 and the second antenna is coupled to the second RFIO port 211), an external antenna multiplexer switch (such as the external antenna multiplexer switch 242 identified as “Antenna Mux Switch 242” in FIG. 2B) may be unnecessary. In a two-antenna example (not shown), the second RFFE 201 may be used in a full or half-duplex mode.

In the example of FIG. 2B, the second RFFE 201 utilizes one antenna, namely, the antenna 202. As with FIG. 2A, the antenna 202 may be a single antenna or an antenna array, which are both generally represented herein by the antenna 202 for case of illustration and not limitation. In the example of FIG. 2B with the exemplified use of the separate first port (i.e., the xLNA_in port 240) dedicated to RF reception, and the second port (i.e., the second RFIO port 211) dedicated to RF transmission, an external antenna multiplexer switch 242 may be utilized as shown. The external antenna multiplexer switch 242 may also be referred to as an external transmit/receive switch. The external antenna multiplexer switch 242 may selectively couple a common port (coupled to the antenna 202, also referred to as an antenna port herein) to either an output port (coupled to an external LNA 244 in the example of FIG. 2B) or an input port (coupled to the power amplifier 204 via the power amplifier balun 206 and the second RFIO port 211 in the example of FIG. 2B) of the external antenna multiplexer switch 242.

As illustrated in the example of FIG. 2B, the external LNA 244 (labeled “xLNA”) is configured to receive a signal (e.g., traffic and/or control signal) from an output of the external antenna multiplexer switch 242. The external LNA 244 is configured to amplify that signal (while minimizing the amplification of noise) and present the amplified signal to the xLNA_in port 240. After passing through the iLNA input matching circuitry 238, the amplified signal is presented to the iLNA 208 for additional (low noise) amplification. Accordingly, in the configuration of FIG. 2B, the iLNA 208 may be considered a post-amplifier (as it is receiving and amplifying the signal already amplified by the external LNA 244).

For purposes of discussion and not limitation, a configuration of FIG. 2A may be referred to as an “iLNA configuration” or an “iLNA mode” and a configuration of FIG. 2B may be referred to as an “xLNA configuration” or an “xLNA mode.” In comparing the iLNA configuration of FIG. 2A to the xLNA configuration of FIG. 2B, it may be recognized that the xLNA configuration of FIG. 2A may sustain a first performance degradation that is not sustained in the iLNA configuration of FIG. 2A. Namely, the first performance degradation may include signal attenuation (loss) associated with passing a signal through the external antenna multiplexer switch 242. This signal attenuation directly increases the system noise figure and decreases the system gain (where the system includes the external antenna multiplexer switch 242, the external LNA 244, and the second RFFE 201). Additionally, using the external antenna multiplexer switch 242 in the xLNA configuration adds cost to the system (compared to a system that does not include the external antenna multiplexer switch 242).

However, the iLNA configuration of FIG. 2A may sustain a second performance degradation associated with using concurrent matching 236. Namely, the concurrent matching 236 optimizes the match for transmission and reception (which are not always at the same frequencies) and, therefore, may sacrifice performance at one frequency to improve an overall match across all transmission and reception operating frequencies. In particular, in the iLNA configuration example of FIG. 2A, matching the input impedance of the iLNA 208 (at the LNA input 212 to, for example, reduce reflections from that port) may be difficult because of the additional need to match the second RFIO port 211 for power amplifier transmission. Such a difficulty may be referred to as power amplifier loading herein. Power amplifier loading may increase the input impedance variation (as seen at the first RFIO port 210) over the system's operating band. The parasitic capacitance of the power amplifier may also degrade the performance of the iLNA 208.

However, comparing the xLNA configuration of FIG. 2B to the iLNA configuration of FIG. 2A, it may be understood that the xLNA configuration of FIG. 2B may improve RF system performance by utilizing the external LNA 244 before applying a received signal to the xLNA_in port 240 of the second RFFE 201. The improved performance may be realized because the external LNA 244 may be tuned for peak performance in the receive operating band of the system without the degradation of power amplifier loading experienced in connection with the iLNA configuration of FIG. 2A. Additionally, the iLNA input matching circuitry 238 in combination with the iLNA 208 of FIG. 2B may be tuned for peak performance in the receive operating band of the system, also without a need to address the power amplifier loading degradation described in connection with the iLNA configuration of FIG. 2A.

Wireless communication device (e.g., apparatus, scheduled entity, mobile device) manufacturers may prefer either the iLNA configuration or the xLNA configuration for their RFFEs. Described herein are methods and apparatus that facilitate the manufacture and use of one RFFE configured to provide either the iLNA configuration or the xLNA configuration. In some examples, the ability to manufacture and use one RFFE that offers both alternative configurations may be facilitated by the use of an additional (internal) low noise amplifier as a dummy load in the iLNA configuration and by reuse of the additional (internal) low noise amplifier as a post-amplifier receiving a signal from an external low noise amplifier in the xLNA configuration. The examples described herein utilize the iLNA 208 (present in both the iLNA configuration of the first RFFE 200 of FIG. 2A and the xLNA configuration of the second RFFE 201 of FIG. 2B) and the just mentioned additional iLNA to achieve the results described herein.

In the examples described herein, in the iLNA configuration, the iLNA 208 serves as the first amplification stage (i.e., the first LNA stage) in a receiver chain, while the additional iLNA (fabricated in the same internal LNA core as the iLNA 208) serves as the dummy load in a single-ended to differential transformer. In the xLNA configuration, the additional iLNA serves as a post-amplification stage (i.e., a stage of amplification following the first amplification stage performed by an external LNA 244) in a receiver chain.

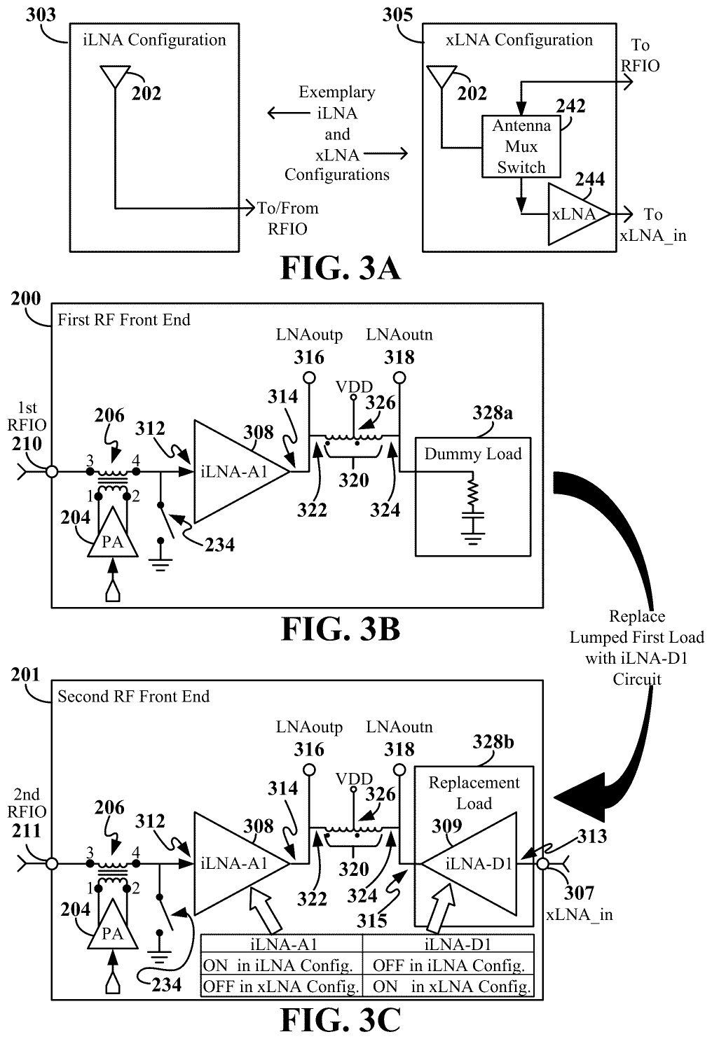

FIGS. 3A, 3B, and 3C are simplified block diagrams of two external equipment configurations associated with two RFFEs according to some aspects of the disclosure. FIG. 3A includes block diagrams of first external components 303 coupled to an RFFE in an iLNA configuration and second external components 305 coupled to an RFFE in an xLNA configuration, according to some aspects of the disclosure. According to some aspects, the first external components 303 that may be coupled to the first RFFE 200 in the iLNA configuration includes the antenna 202. The input/output of the first external components 303 coupled to the first RFFE 200 in the iLNA configuration, is configured to couple with the first RFIO port 210 of the first RFFE 200 of FIG. 3B.

According to some aspects, the second external components 305 that may be coupled to the second RFFE 201 in the xLNA configuration include the antenna 202, the external antenna multiplexer switch 242, and the external LNA 244. The antenna port of the external antenna multiplexer switch 242 is configured to couple to the antenna 202. The input port of the external antenna multiplexer switch 242 is configured to couple with the second RFIO port 211 of the second RFFE 201 of FIG. 3C. The output port of the external antenna multiplexer switch 242 is configured to couple to the xLNA_in port 307 of the second RFFE 201 of FIG. 3C.

FIG. 3B is a block diagram of the first RFFE 200, which may only be configured to work in the iLNA configuration because it has a single RFIO port, namely the first RFIO port 210 (that serves as both a transmitter output port and a receiver input port). The first RFFE 200 includes a power amplifier 204, a power amplifier balun 206, an internal transmit/receive switch 234, and an internal low noise amplifier, iLNA-A1 308. The nomenclature iLNA-A1 308 indicates that the referenced LNA is an internal LNA (fabricated on an internal LNA core); the iLNA-A1 308 is included in a set of iLNAs identified with the letter A. In the set of iLNAs identified with the letter A, iLNA-A1 308 is the first of n LNAs, where n is a positive integer. The iLNA-A1 308 has a first LNA input 312 and a first LNA output 314.

The first RFFE 200 also includes an internal LNA load inductor 320 (also referred to herein as an inductor or a load inductor), which includes a first inductor node 322 coupled to the first LNA output 314 and an LNAoutp 316 terminal. A second inductor node 324 may be coupled to an LNAoutn 318 terminal. A center inductor node 326 may be coupled to VDD. The second inductor node 324 and the LNAoutn 318 terminal are coupled to a first load (e.g., also referred to as a dummy load 328a), which includes (for purposes of discussion and not limitation) a lumped element series combination of a resistor and a capacitor. In some examples, the values of R (e.g., several thousand Ohms) and C (e.g., several pF) are chosen to improve a balance between the LNAoutp 316 and the LNAoutn 318 terminals. However, chip performance is not particularly sensitive to the impedance of the dummy load 328a as long as the total impedance is large. For example, any common-mode signal due to an impedance mismatch may be addressed by the differential nature of the receiver chain following the single-ended to differential transformer (configured as the internal LNA load inductor 320).

FIG. 3C is identical to FIG. 3B with one exception. The exception is that the dummy load 328a is replaced by a second load (also referred to as a replacement load 328b). The replacement load 328b includes an additional internal LNA, iLNA-D1 309. The nomenclature iLNA-D1 309 indicates that the referenced LNA is an internal LNA (fabricated on the internal LNA core); the iLNA-D1 309 is in a set of iLNAs identified with the letter D. In the set of iLNAs identified with the letter D, iLNA-D1 309 is the first of n LNAs, where n is a positive integer. The iLNA-A1 309 has a second LNA input 313 and a second LNA output 315.

The second RFFE 201 is configured to operate either in the iLNA configuration or the xLNA configuration. In the iLNA configuration, iLNA-A1 308 serves as a first amplification stage (i.e., the first LNA stage) in a receiver chain, while the additional internal iLNA, iLNA-D1 309, serves as the replacement load 328b (i.e., a replacement of the dummy load 328a) in a single-ended to differential transformer (configured as the internal LNA load inductor 320). In the xLNA configuration, the additional internal LNA, iLNA-D1 309, serves as a post-amplification stage (i.e., a stage of amplification following the first amplification stage performed by the external LNA 244 of FIG. 3A) in a receiver chain. In the xLNA configuration, the iLNA-A1 308 serves as the dummy load in the single-ended to differential transformer (configured as the internal LNA load inductor 320). In practice, the resistance capacitance (RC) impedance of the dummy load may or may not be equal to the LNA output impedance on the other side of the internal LNA load inductor 320.

Additionally, according to aspects described herein, the output impedance of the iLNA-D1 309 (i.e., the impedance looking into the output of the iLNA-D1 309) need not necessarily be equivalent to the impedance of the RC load it replaces. At least one reason for a relaxation to load equivalency may be that the chip performance is not sensitive to the impedance at this node (e.g., the node coupled to either the dummy load 328a or the replacement load 328b). Impedance variation at this node may create a common-mode output signal (which may have a minimal magnitude); however, the stages of the receiver chain following each LNA are fully-differential circuits, so any common-mode output signal should not affect other performance parameters.

In greater detail, the second RFFE 201 of FIG. 3C (i.e., an apparatus) includes the internal LNA load inductor 320 having a first inductor node 322 at a first end, a second inductor node 324 at a second end, and a center inductor node 326 between the first end and the second end. The second RFFE 201 also includes a first low noise amplifier (iLNA-A1 308) having the first LNA input 312 and the first LNA output 314, the first LNA output 314 coupled to the LNAoutp 316 terminal. The second RFFE 201 also includes a second LNA (iLNA-D1 309) having the second LNA input 313 and the second LNA output 315, the second LNA output 315 coupled to an LNAoutn 318 terminal. The second RFFE 201 also includes a first load, configured as the second LNA (iLNA-D1 309) in an off state, coupled to the second inductor node 324 (while the first LNA (iLNA-A1 308) is in an on state). Alternatively, the second RFFE 201 may include a second load, configured as the first LNA (iLNA-A1 308) in the off state, coupled to the first inductor node 322 (while the second LNA (iLNA-D1 309) is in an on state).

In other words, as indicated in the text of FIG. 3C, in iLNA configuration, iLNA-A1 308 may be in an on state, while iLNA-D1 309 is in an off state. In the xLNA configuration, iLNA-A1 308 may be in an off state, while iLNA-D1 309 is in an on state.

FIGS. 4A and 4B are simplified block diagrams and schematics of an internal low noise amplifier core configured as at least a portion of an RFFE 400 according to some aspects of the disclosure. FIG. 4A is a simplified block diagram illustrating a portion of the second RFFE 201 of FIG. 3B, adding two switches (e.g., a first switch 460 and a second switch 462, where both switches are SPST switches) between the LNAs (iLNA-A1 308 and iLNA-D1 309) and the internal LNA load inductor 320. The first switch 460 and the second switch 462 may reduce capacitive parasitics associated with the LNAs.

The configuration of FIG. 4A may support operation in either the iLNA configuration or an xLNA configuration. The example includes a first internal low noise amplifier, iLNA-A1 308. The iLNA-A1 308 has the first LNA input 312 and the first LNA output 314. The example also includes a second internal low noise amplifier, iLNA-D1 309. The iLNA-D1 309 has the second LNA input 313 and the second LNA output 315. The first switch 460 is coupled to the first LNA output 314. The second switch 462 is coupled to the second LNA output 315. An internal LNA load inductor 320 includes a first inductor node coupled to the first LNA output 314 via the first switch 460 and also coupled to the LNAoutp 316 terminal. A second inductor node may be coupled to the second LNA output 315 via the second switch 462 and also coupled to the LNAoutn 318 terminal. A center inductor node may be coupled to VDD.

FIG. 4B is a representation of the block diagram of FIG. 4A with the LNAs and SPST switches replaced by NMOS transistors according to some aspects of the disclosure. For example, the first switch 460 may be realized using a first NMOS transistor 464. The first LNA, iLNA-A1 308, may be realized using a cascode pair of NMOS transistors, where a second NMOS transistor 468 is a cascode stage, and a third NMOS transistor 470 is the transconductance amplifier (configured as a low noise amplifier). Similarly, the second switch 462 may be realized using a fourth NMOS transistor 466. The second LNA, iLNA-D1 309, may be realized using a cascode pair of NMOS transistors, where a fifth NMOS transistor 472 is a cascode stage, and a sixth NMOS transistor 474 is the transconductance amplifier (configured as a low noise amplifier).

As indicated in the text of FIG. 4B, in an iLNA configuration, the first switch 460 (SW1) may be in a closed state (the second switch 462 (SW2) may be in an open state), iLNA-A1 308 may be in an on state, while iLNA-D1 309 is in an off state. In an xLNA configuration, the first switch 460 (SW1) may be in an open state (the second switch 462 (SW2) may be in a closed state), iLNA-A1 308 may be in an off state, while iLNA-D1 309 is in an on state.

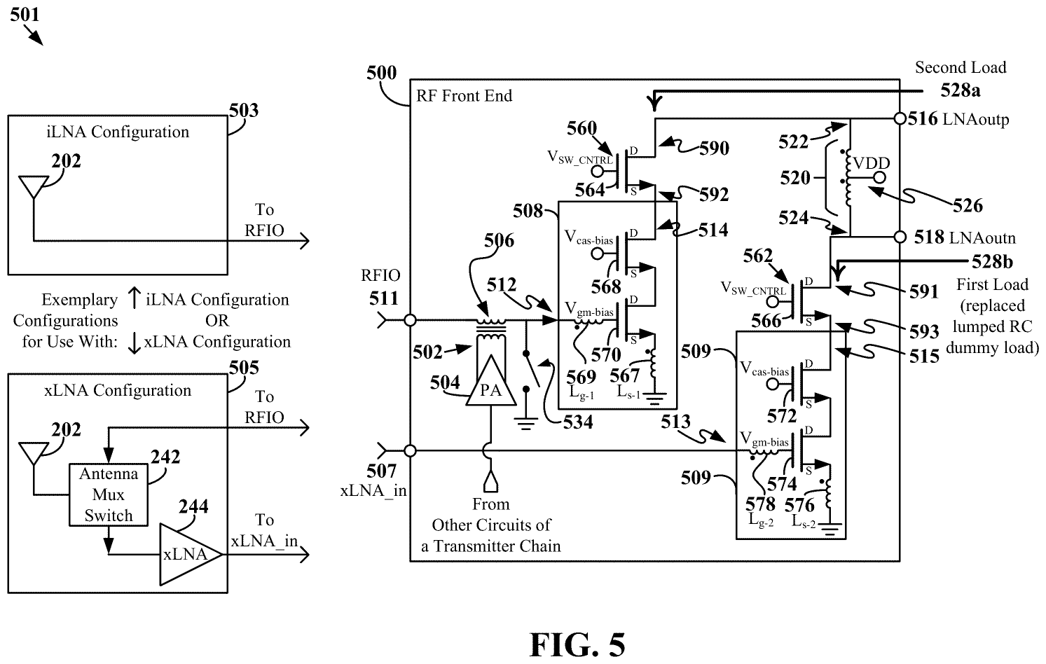

FIG. 5 is a schematic drawing of an RFFE 500 configurable in an iLNA configuration (with first external components 503) or an xLNA configuration (with second external components 505), according to some aspects of the disclosure. According to some aspects, the first external components 503 that may be coupled to the RFFE 500 in the iLNA configuration includes the antenna 202. The input/output of the first external components 503 is configured to couple with an RFIO port 511 of the RFFE 500 of FIG. 5.

According to some aspects, the second external components 505 that may be coupled to the RFFE 500 in the xLNA configuration include the antenna 202, the external antenna multiplexer switch 242, and the external LNA 244. The antenna port of the external antenna multiplexer switch 242 is configured to couple to the antenna 202. The input port of the external antenna multiplexer switch 242 is configured to couple with the RFIO port 511 of the RFFE 500. The output port of the external antenna multiplexer switch 242 is configured to couple to the xLNA_in port 507 of the RFFE 500.

The RFFE 500 may be configured in the iLNA configuration, where the RFIO port 511 may serve as both a transmitter output port and a receiver input port. Alternatively, the RFFE 500 may be configured in the xLNA configuration, where the RFIO port 511 may serve as a transmitter output port, and the xLNA_in port 507 may serve as a receiver input port.

The RFFE 500 includes a power amplifier 504, a power amplifier balun 506, and an internal transmit/receive switch 534, similar to the power amplifier 204, power amplifier balun 206, and internal transmit/receive switch 234, as shown and described in connection with FIG. 2A and FIG. 2B. The RFFE 500 further includes a first low noise amplifier (LNA) 508, similar to iLNA-A1 308 as shown and described in connection with FIG. 3C. The first LNA 508 has a first LNA input 512 and a first LNA output 514. The RFFE 500 further includes a second LNA 509, similar to iLNA-D1 309 as shown and described in connection with FIG. 3C. The second LNA 509 has a second LNA input 513 and a second LNA output 515.

According to some aspects, a system 501 may include the RFFE 500 in combination with the first external components 503 (e.g., including the antenna 202) and configured in an iLNA configuration, or the system 501 may include the RFFE 500 in combination with the second external components 505 (e.g., including the antenna 202, the external antenna multiplexer switch 242, and the xLNA 244) and configured in an xLNA configuration. Accordingly, in some examples, the system 501 (e.g., the apparatus) may include the load inductor 520, the first switch 560, the second switch 562, the first LNA 508, and the second LNA 509 as components of RFFE 500, and the system 501 may also include an xLNA 244 having an xLNA input and an xLNA output (where the xLNA 244 is separate from the RFFE 500). The xLNA output may be coupled to the second LNA input 513.

In some examples, the RFFE 500 may include the power amplifier 504 having the power amplifier output 502 coupled to the first LNA input 512 via a power amplifier balun 506, and an internal transmit/receive switch 534 coupled in parallel between the power amplifier balun 506 and the first LNA input 512. The power amplifier 504 may receive input from other circuits of a transmitter chain (not shown), as indicated in FIG. 5. In some examples, in an iLNA configuration, the antenna 202 may couple to the power amplifier balun 506 (and the first LNA input 512 via the RFIO port 511). In other examples, in an xLNA configuration, the antenna 202 may couple to an antenna port of an external antenna multiplexer switch 242, separate from the RFFE 500 and different from the internal transmit/receive switch 534. In an xLNA configuration, an output of the external antenna multiplexer switch 242 may couple to an xLNA input of the xLNA 244, and an output of the xLNA 244 may couple to an xLNA_in 507 port of the RFFE 500. The external antenna multiplexer switch 242 input may couple to the power amplifier balun 506 via the RFIO port 511.

The first LNA 508 includes a first transconductance low noise amplifier transistor 570 in series with a first cascode transistor 568. The first transconductance low noise amplifier transistor 570 includes a source terminal coupled to ground via a first source inductor 567 (Ls-1), a gate terminal coupled to the first LNA input 512 via a first gate inductor 569 (Lg-1), and a drain terminal coupled to a source terminal of the first cascode transistor 568. The first cascode transistor 568 includes a source terminal coupled to the drain terminal of the first transconductance low noise amplifier transistor 570, a gate terminal coupled to an LNA state circuit (e.g., a circuit configured to change a state of the first internal low nose amplifier between the on and off states) (not shown), and a drain terminal corresponding to the first LNA output 514. The drain terminal of the first cascode transistor 568 is coupled to a source terminal of a first switch transistor 564. The drain terminal of the first switch transistor 564 is coupled to the LNAoutp 516 terminal. The gate terminal of the first switch transistor 564 is coupled to a switch control circuit (not shown).

The RFFE 500 also includes a load inductor 520. The load inductor 520 may be an internal LNA load inductor similar to the internal LNA load inductor 220 or internal LNA load inductor 320 as shown and described in connection with FIGS. 2A, 2B, 3B, 3C, 4A, and/or 4B. The load inductor 520 may include a first inductor node 522 that may be coupled to an LNAoutp 516 terminal. The load inductor 520 may include a second inductor node 524 that may be coupled to an LNAoutn 518 terminal. A center inductor node 526 may be coupled to VDD. The second inductor node 524 and the LNAoutn 518 terminal may be coupled to a first load 528b (similar to the replacement load 328b as shown and described in connection with FIG. 3C). The coupling may be via a second switch 562. The load inductor 520, the first inductor node 522, the second inductor node 524, and the center inductor node 526 may be similar to the internal LNA load inductor 220, the first inductor node 222, the second inductor node 224, and the center inductor node 226 as shown and described in connection with FIGS. 2A and 2B.

The first load 528b may include the second low noise amplifier (LNA) 509, similar to iLNA-D1 309 as shown and described in connection with FIG. 3C. The second LNA 509 may include a second transconductance transistor 574 in series with a second cascode transistor 572.

The second transconductance transistor 574 includes a source terminal coupled to ground via a second source inductor 576 (Ls-2), a gate terminal coupled to a second LNA input 513 via a second gate inductor 578 (Lg-2), and a drain terminal coupled to a source terminal of the second cascode transistor 572. The second cascode transistor 572 includes a source terminal coupled to the drain terminal of the second transconductance transistor 574, a gate terminal coupled to an LNA state circuit (e.g., a circuit configured to change a state of the second internal low nose amplifier between the on and off states) (not shown), and a drain terminal that also serves as a second LNA output 515. The drain terminal of the second cascode transistor 572 may be coupled to a source terminal of a second switch transistor 566. The drain terminal of the second switch transistor 566 may be coupled to the LNAoutn 518 terminal. The gate terminal of the second switch transistor 566 may be coupled to a switch control circuit (not shown).

The RFFE 500 also includes a first switch 560 and a second switch 562. The first switch 560 includes a first terminal 590 and a second terminal 592. The first terminal 590 and the second terminal 592 may be selectively opened or closed. The selectively opened or closed state of the first switch 560 may be exercised by a switch state circuit (e.g., a circuit configured to change a state of the first switch 560 between the open and closed states) (not shown) coupled to the gate of the first switch 560.

The second switch 562 includes a third terminal 591 and a fourth terminal 593 (where the first switch 560 includes the first terminal 590 and the second terminal 592). The third terminal 591 and the fourth terminal 593 may be selectively opened or closed. The selectively opened or closed state of the second switch 562 may be exercised by the switch state circuit (e.g., a circuit configured to change a state of the second switch 562 between the opened and closed states) (not shown) coupled to the gate of the second switch 562.

The first LNA 508 may be coupled to the first inductor node 522 via the first switch 560. The second LNA 509 may be coupled to the second inductor node 524 via the second switch 562. The states of the first LNA 508 and the second LNA 509 may be controlled by an LNA state circuit (e.g., a circuit configured to change the respective states of the LNAs between an on state and an off state). The first switch 560 and the second switch 562 may reduce the capacitive parasitic from the distributive cascode transistors (first cascode transistor 568 and second cascode transistor 572). The first switch 560 and the second switch 562 may be referred to as head switches. In one example, all transistors described herein are NMOS transistors.

In greater detail, the RFFE 500 (e.g., and apparatus) may include the load inductor 520. The load inductor 520 may be an internal LNA load inductor. The load inductor 520 may have a first inductor node 522 at a first end, a second inductor node 524 at a second end, and a center inductor node 526 between the first end and the second end. The RFFE 500 may also include a first switch 560 having a first terminal 590 and a selectively opened or closed second terminal 592, the first terminal 590 coupled to the first inductor node 522. The RFFE 500 may also include a second switch 562 having a third terminal 591 and a selectively opened or closed fourth terminal 593, the third terminal 591 coupled to the second inductor node 524. The RFFE 500 may also include a first low noise amplifier (LNA) 508 having the first LNA input 512 and first LNA output 514, the first LNA output 514 coupled to the selectively opened or closed second terminal 592 of the first switch 560. The RFFE may still further include a second LNA 509 having the second LNA input 513 and the second LNA output 515, the second LNA output 515 coupled to the selectively opened or closed fourth terminal 593 of the second switch 562. A first load 528b may be configured as a first series combination of the second switch 562 in an open state and the second LNA 509 in an off state. The first load 528b may be coupled to the second inductor node 524. Alternatively, a second load 528a may be configured as a second series combination of the first switch 560 in the open state and the first LNA 508 in the off state. The second load 528a may be coupled to the first inductor node 522.

In some examples, the first load 528b may be coupled to the second inductor node 524 in response to the apparatus being configured to transform a single-ended input at the first LNA input 512 to an amplified differential output across the first inductor node 522 and the second inductor node 524. The second load 528a may be coupled to the first inductor node 522 in response to the apparatus being configured to transform the single-ended input at the second LNA input 513 to the amplified differential output across the first inductor node 522 and the second inductor node 524.

As illustrated in the drawings, a polarity of the first inductor node 522 relative to the center inductor node 526 is opposite to the polarity of the second inductor node 524 relative to the center inductor node 526. Also, as illustrated in the examples, the first switch 560 and the second switch 562 may be configured as respective single-pole-single-throw switches.

In some examples, the first switch 560, the second switch 562, the first LNA 508, and the second LNA 509 may be fabricated as a single core circuit. In some examples, the single core circuit includes the respective input matching networks coupled to the first LNA 508 and the second LNA 509. Furthermore, the first LNA 508 and the second LNA 509 may be duplicates (e.g., one of two or more identical things).

In some examples, the first LNA 508 may include a first transconductance low noise amplifier transistor 570 coupled in series with a first cascode transistor 568, and the second LNA 509 may include a second transconductance transistor 574 coupled in series with a second cascode transistor 572. In some examples, each of the first LNA 508 and the second LNA 509 may respectively include: a first n-channel metal-oxide semiconductor (NMOS) transistor (e.g., first transconductance low noise amplifier transistor 570, second transconductance transistor 574) having a first drain, a first gate, and a first source configured as a transconductance amplifier; and a second NMOS transistor (e.g., 568, 572) having a second drain, a second gate, and a second source configured as a cascode amplifier, where: the first gate corresponds to the first LNA input 512 and the second LNA input 513, respectively, the first source is coupled to ground, the first drain is coupled to the second source, the second drain corresponds to the first LNA output 514 and the second LNA output 515, respectively, a first direct current (DC) voltage bias is coupled to the first gate, and a second DC voltage bias is coupled to the second gate. In some examples, the first source may be coupled to ground via a source inductor (e.g., 567, 576).

In some examples, the apparatus may further include an external LNA (xLNA 244) coupled to the second LNA input 513. The first LNA 508 and the second LNA 509 may be a first plurality of low noise amplifiers and a second plurality of low noise amplifiers, respectively, each of the first plurality of low noise amplifiers and the second plurality of low noise amplifiers having a corresponding plurality of distinct gains, and the apparatus may be further configured to: select one of the first plurality of low noise amplifiers to be the first low noise amplifier and turn off all other ones of the first plurality of low noise amplifiers, or select one of the second plurality of low noise amplifiers to be the second low noise amplifier and turn off all other ones of the second plurality of low noise amplifiers.

Accordingly, as described above, the second LNA 509 may be used as a dummy load in instances where the first LNA 508 is in an on state and receiving a single-ended input signal and the second LNA is in an off state. The second LNA 509 may be reused as a post-amplifier to the xLNA 244 in instances where the second LNA 509 is in the on state and receiving the single-ended input signal via the xLNA 244 (and the first LNA 508 is in the off state and serving as a dummy load).

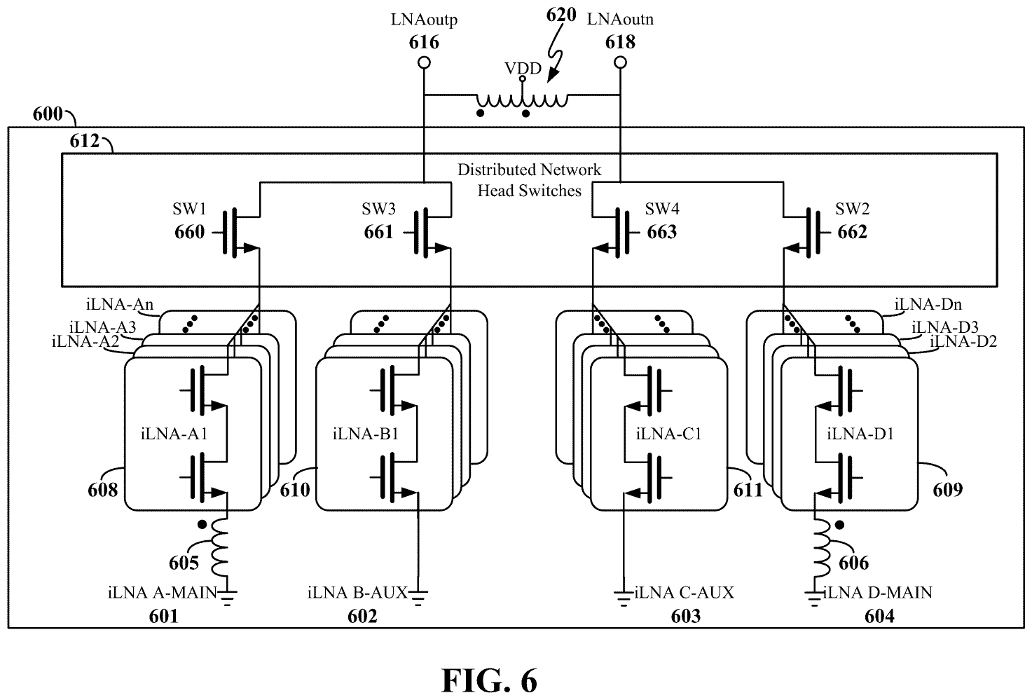

FIG. 6 is a schematic representation of an LNA core 600 according to some aspects of the disclosure. The LNA core 600 includes four sets of internal LNAs (i.e., LNAs configured in the LNA core 600). Each set may include “n” LNAs, where n is a positive number greater than zero. Each of the n LNAs in a given set is preconfigured with a known gain. An apparatus may change the gain of an LNA by changing the LNA being used in the given set.

A first set 601 of LNAs is identified as the iLNA A-MAIN set. Each LNA in the iLNA A-MAIN set includes a source inductor coupled to ground (e.g., source inductor 605, only shown with the first LNA (iLNA-A1 608) to avoid cluttering the drawing). Each LNA associated with the first set 601 includes the letter “A” in its identifier. The first LNA in the first set 601, iLNA-A1 608, may be similar to the first LNA 308 as shown and described in connection with FIGS. 3B and 3C, for example. Other representative LNAs in the first set 601 include iLNA-A2, iLNA-A3, . . . , iLNA-An. The iLNA A-MAIN set (first set 601) may be used for high-performance applications.

A second set 602 of LNAs is identified as the iLNA B-AUX set. Each LNA in the iLNA B-AUX set has its source tied directly to ground (only shown with the first LNA (iLNA-B1 610) to avoid cluttering the drawing). Each LNA associated with the second set 602 includes the letter “B” in its identifier. Other representative LNAs in the second set 602 include iLNA-B2, iLNA-B3, . . . , iLNA-Bn (not labeled in the drawing to avoid cluttering the drawing). The iLNA B-AUX set (second set 602) may be used for non-high-performance applications.

A third set 603 of LNAs is identified as another auxiliary set, the iLNA C-AUX set. Each LNA in the iLNA C-AUX set has its source tied directly to ground (only shown with the first LNA (iLNA-C1 611) to avoid cluttering the drawing). Each LNA associated with the third set 603 includes the letter “C” in its identifier. Other representative LNAs in the third set 603 include iLNA-C2, iLNA-C3, . . . , iLNA-Cn (not labeled in the drawing to avoid cluttering the drawing). The iLNA C-AUX set (third set 603) may also be used for non-high-performance applications.

A fourth set 604 of LNAs is identified as another main set, the iLNA D-MAIN set. Each LNA in the iLNA D-MAIN set includes a source inductor coupled to ground (e.g., source inductor 606, only shown with the first LNA (iLNA-D1 609) to avoid cluttering the drawing). Each LNA associated with the fourth set 604 includes the letter “D” in its identifier. The first LNA in the fourth set 604, iLNA-D1 609, may be similar to the second LNA 309 as shown and described in connection with FIG. 3C, for example. Other representative LNAs in the fourth set 604 include iLNA-D2, iLNA-D3, . . . , iLNA-Dn. The iLNA D-MAIN set (fourth set 604) may be used for high-performance applications.

FIG. 6 also illustrates an internal LNA load inductor 620, similar to the internal LNA load inductor 220, 320 or the load inductor 520 as shown and described in connection with FIGS. 2A, 2B, 3C, 3D, 4A, 4B, and 5. FIG. 6 also illustrates an LNAoutp 616 terminal and an LNAoutn 618 terminal, similar to the LNAoutp 216, 316, 516 terminals and the LNAoutn 218, 318, 518 terminals, as shown and described in connection with FIGS. 2A, 2B, 3B, 3C, 4A, 4B, and 5.

To reduce the capacitive parasitics from the distributive cascode transistors of the pluralities of LNAs in each of the four sets of LNAs (first set 601, second set 602, third set 603, and fourth set 604), four NMOS “head switches” (SW1 660, SW2 662, SW3 661, and SW4 663) (in a distributed network of head switches 612) are added between the internal LNA load inductor 620 and the pluralities of LNAs in the LNA core. The first switch, SW1 660, may be similar to the first switch 460 and the first switch 560 as shown and described in connection with FIGS. 4A, 4B, and 5. The second switch, SW2 662, may be similar to the second switch 462 and the second switch 562 as shown and described in connection with FIGS. 4A, 4B, and 5. According to aspects described herein, one switch of the four NMOS head switches may be opened (i.e., in an on state) while the remaining three are closed (i.e., each in an off state).

Performance parameters associated with the use of the pluralities of LNAs according to the examples described herein are presented in Table 1 (for operation in an iLNA configuration and configured for maximum gain and minimum noise figure) and Table 2 (for operation in an xLNA configuration and configured for maximum gain and minimum noise figure).

TABLE 1
iLNA Configuration

| | | Receiver Noise |
|---|---|---|
| | Receiver Noise | Figure |
| | Figure | Without Switches |
| | With Switches | 660, 661, 662, and |
| Frequency | 660, 661, 662, 663 | 663 |
| (MHz) | (dB) | (dB) |
| 5180 | 5.8 | 6.2 |
| 5500 | 6.7 | 7.3 |
| 5845 | 7.1 | 7.5 |
| 6200 | 7.0 | 8.0 |
| 6425 | 7.5 | 9.2 |

TABLE 2
xLNA Configuration

| | Receiver Noise |
|---|---|
| | Figure |
| | With Switches |
| Frequency | 660, 661, 662, 663 |
| (MHz) | (dB) |
| 5180 | 4.8 |
| 5500 | 4.4 |
| 5845 | 4.8 |
| 6200 | 4.6 |
| 6425 | 5.1 |

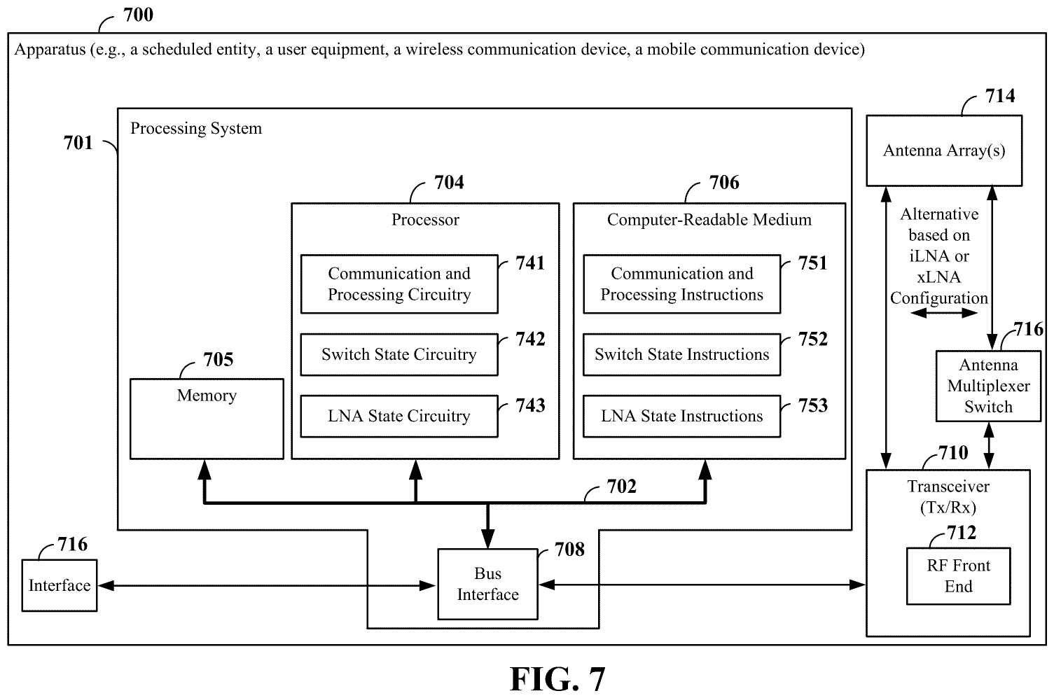

FIG. 7 is a block diagram illustrating an example of a hardware implementation of an apparatus 700 (e.g., a scheduled entity, a user equipment, a wireless communication device, a mobile communication device) employing one or more processing systems (generally represented by processing system 701) according to some aspects of the disclosure. The apparatus 700 may be similar to, for example, any of the scheduled entities, user equipment, wireless communication devices, and mobile communication devices as shown and described in connection with FIG. 1. The apparatus 700 may include any of the circuitry described and illustrated, for example, in FIGS. 2-6.

In accordance with various aspects of the disclosure, an clement, any portion of an element, or any combination of elements may be implemented with a processing system 701 that includes one or more processors, generally represented by processor 704. Examples of processor 704 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the apparatus 700 may be configured to perform any one or more of the functions described herein. That is, the one or more processors (generally represented by processor 704), as utilized in the apparatus 700, may be configured to, individually or collectively, implement any one or more of the methods or processes described and illustrated, for example, in or in connection with FIGS. 2-6.

In this example, the processing system 701 may be implemented with a bus architecture, represented generally by the bus 702. The bus 702 may include any number of interconnecting buses and bridges depending on the specific application of the processing system 701 and the overall design constraints. The bus 702 communicatively couples together various circuits, including one or more processors (represented generally by the processor 704), one or more memories (represented generally by a memory 705), and one or more computer-readable media (represented generally by the computer-readable medium 706). The bus 702 may also link various other circuits such as timing sources, peripherals, voltage regulators, and power management circuits, which are well known to persons having ordinary skill in the art and, therefore, will not be described any further.

A bus interface 708 provides an interface between the bus 702 and one or more transceivers (represented generally by transceiver 710). The transceiver 710 may be, for example, a wireless transceiver. The transceiver 710 may be operational with multiple RATs (e.g., LTE, 5G NR, IEEE 802.11 (WiFi®), etc.). The transceiver 710 may provide respective means for communicating with various other apparatus, scheduling entities, UEs, and core networks over a transmission medium (e.g., air interface).

In some examples, the transceiver 710 may include an RF front end (RFFE) 712, similar to any of the first RFFE 200, second RFFE 201, RFFE 400, and RFFE 500 as shown and described in connection with FIGS. 2-5. The transceiver 710 may be coupled to one or more antenna, or antenna array(s) 712. The antenna array(s) 712 may be similar to the antenna 202, as shown and described in connection with FIGS. 2A, 2B, 3A, and 5. The bus interface 708 may provide an interface between the bus 702 and a user interface 716 (e.g., keypad, display, touch screen, speaker, microphone, control features, vibration circuit/device, etc.). The user interface 716 is optional and may be omitted in some examples. The bus interface 708 may also provide an interface between the bus 702 and the transceiver 710, including an interface with the RFFE 712, for example and without limitation.

One or more processors, represented individually and collectively by processor 704, may be responsible for managing the bus 702 and general processing, including the execution of software stored in the memory 705 and/or on the computer-readable medium 706. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on the computer-readable medium 706. The software, when executed by the processor 704, causes the processing system 701 to perform the various processes and functions described herein for any particular apparatus.

The computer-readable medium 706 may be a non-transitory computer-readable medium and may be referred to as a computer-readable storage medium or a non-transitory computer-readable medium. The non-transitory computer-readable medium may store computer-executable code (e.g., processor-executable code). The computer executable code may include code for causing a computer (e.g., a processor) to implement one or more of the functions described herein. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium 706 may reside in the processing system 701, be external to the processing system 701, or be distributed across multiple entities, including the processing system 701. The computer-readable medium 706 may be embodied in a computer program product or article of manufacture. By way of example, a computer program product or article of manufacture may include a computer-readable medium in packaging materials. In some examples, the computer-readable medium 706 may be part of the memory 705. Persons having ordinary skill in the art will recognize how best to implement the described functionality presented throughout this disclosure depending on the particular application and the overall design constraints imposed on the overall system. The computer-readable medium 706 and/or the memory 705 may also be used for storing data that is manipulated by the processor 704 when executing software.

In some aspects of the disclosure, the processor 704 may include communication and processing circuitry 741 configured for various functions, including, for example, communicating with a network entity (e.g., a scheduling entity, a base station, an aggregated or disaggregated base station, an eNB, a gNB, a TRP), another apparatus, and/or a core network. In some examples, the communication and processing circuitry 741 may include one or more hardware components that provide the physical structure that performs processes related to wireless communication (e.g., signal reception and/or signal transmission) and signal processing (e.g., processing a received signal and/or processing a signal for transmission). The communication and processing circuitry 741 may further be configured to execute communication and processing instructions 751 (e.g., software) stored on the computer-readable medium 706 to implement one or more functions described herein.

In some aspects of the disclosure, the processor 704 may include switch state circuitry 742 configured for various functions, including, for example, configuring a first switch having a first terminal and a selectively opened or closed second terminal, the first terminal coupled to a first inductor node, and configuring a second switch having a third terminal and a selectively opened or closed fourth terminal, the third terminal coupled to the second inductor node. Here the inductor may be a load inductor (e.g., an internal LNA load inductor 220, 320 or the load inductor 520 as shown and described in connection with FIGS. 2A, 2B, 3B, 3C, 4A, 4B, and 5) having a first inductor node at a first end, a second inductor node at a second end, and a center inductor node between the first end and the second end. The switch state circuitry 742 may be similar to switch state circuitry of various types of switches, including but not limited to the external antenna multiplexer switch 242, the internal transmit/receive switch 234, the first switch 460, 560, 660, the second switch 462, 562, 662, the third switch SW3 661 and the fourth switch SW4 663, all as shown and described in connection with FIGS. 2-6. In some examples a polarity of the first inductor node relative to the center inductor node is opposite to the polarity of the second inductor node relative to the center inductor node. In some examples, the first switch and the second switch may be configured as respective single-pole-single-throw switches. In some examples, the first switch, the second switch, the first LNA, and the second LNA may be fabricated as a single core circuit. According to some aspects, respective input matching networks coupled to the first LNA and the second LNA may be included in the single core circuit. According to some aspects, the first LNA and the second LNA may be duplicates. The switch state circuitry 742 may be configured to execute switch state instructions 752 (e.g., software) stored on the computer-readable medium 706 to implement the functions described herein.

In some aspects of the disclosure, the processor 2204 may include LNA state circuitry 743 configured for various functions, including, for example, configuring a first LNA having a first LNA input and a first LNA output, the first LNA output coupled to the selectively opened or closed second terminal of the first switch (e.g., first switch 460, 560, 660). In some examples, the LNA state circuitry 743 may be configured for various other functions, including, for example, configuring a second LNA having a second LNA input and a second LNA output, the second LNA output coupled to the selectively opened or closed fourth terminal of the second switch (e.g., second switch 462, 562, 662). In some examples the LNA state circuitry 743 may be configured for various other functions, including, for example, configuring a first load, configured as a first series combination of the second switch in an open state and the second LNA in an off state, where the first load is coupled to the second inductor node, or configuring a second load, configured as a second series combination of the first switch in the open state and the first low noise amplifier in the off state, where the second load is coupled to the first inductor node, all as shown and described, for example, in connection with FIGS. 3C, 4B, and 5.

In some examples, the first load may be coupled to the second inductor node in response to the apparatus being configured to transform a single-ended input at the first LNA input to an amplified differential output across the first inductor node and the second inductor node, or the second load may be coupled to the first inductor node in response to the apparatus being configured to transform the single-ended input at the second LNA input to the amplified differential output across the first inductor node and the second inductor node. In some examples, a respective impedance of the first load and the second load may be equivalent to a series combination of a resistor and a capacitor.

According to some aspects, the first LNA may include a first transconductance low noise amplifier transistor coupled in series with a first cascode transistor, and the second LNA may include a second transconductance transistor coupled in series with a second cascode transistor.

According to some examples, each of the first LNA and the second LNA may include a first n-channel metal-oxide semiconductor (NMOS) transistor having a first drain, a first gate, and a first source configured as a transconductance amplifier, and a second NMOS transistor having a second drain, a second gate, and a second source configured as a cascode amplifier. According to such aspects, the first gate may correspond to the first LNA input and the second LNA input, respectively, the first source may be coupled to ground, the first drain is coupled to the second source, the second drain corresponds to the first LNA output and the second LNA output, respectively, a first direct current (DC) voltage bias may be coupled to the first gate, and a second DC voltage bias may be coupled to the second gate. In some examples, the first source is coupled to ground via a source inductor.

In other examples, LNA state circuitry 743 may further include, or control, an external LNA coupled to the second LNA input. The first LNA and the second LNA may be a first plurality of LNAs and a second plurality of LNAs, respectively. Each of the first plurality of LNAs and the second plurality of LNAs may have a corresponding plurality of distinct gains. In such examples, the apparatus 700, via the LNA state circuitry 743, for example, may select one of the first plurality of LNAs to be the first LNA and turn off all other ones of the first plurality of LNAs, or select one of the second plurality of LNAs to be the second LNA and turn off all other ones of the second plurality of LNAs.

The LNA state circuitry 743 may further be configured to execute LNA state instructions 753 (e.g., software) stored on the computer-readable medium 706 to implement one or more functions described herein.

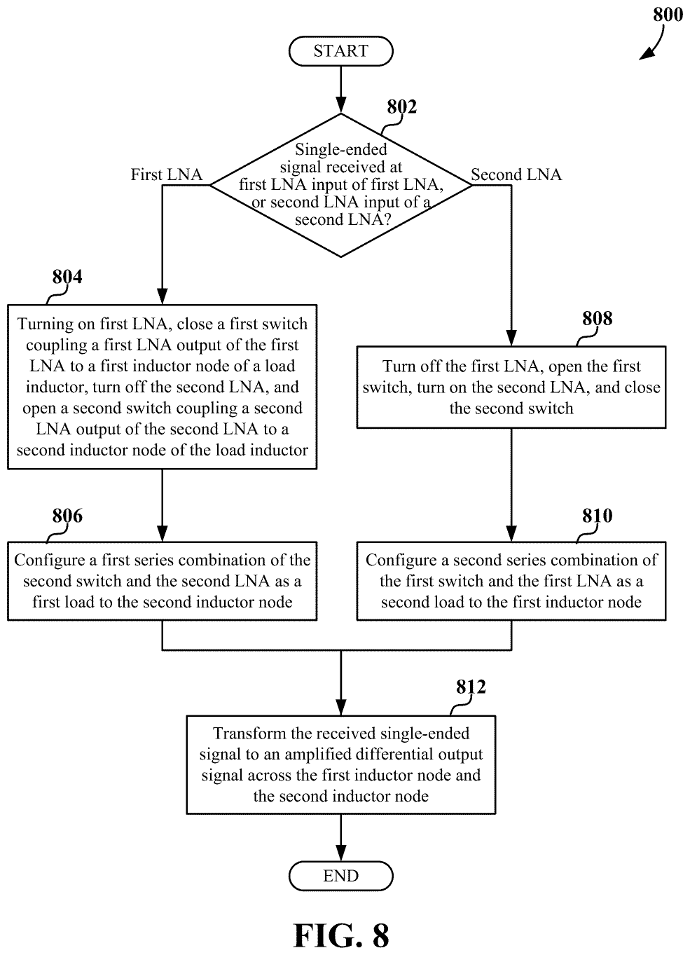

FIG. 8 is a flow chart illustrating an example process 800 (e.g., a method) at an apparatus (e.g., a scheduled entity, a user equipment, a wireless communications device, a mobile communication device) according to some aspects of the disclosure. As described below, some or all illustrated features may be omitted in a particular implementation within the scope of the present disclosure, and some illustrated features may not be required for the implementation of all examples. In some examples, the process 800 may be carried out by the apparatus 700, as shown and described in connection with FIG. 7. The apparatus 700 may be similar to, for example, any of the scheduled entities, user equipment, wireless communications devices, and/or mobile communication devices as shown and described in connection with FIG. 1. The apparatus may incorporate any of the circuits as shown and described in connection with FIGS. 2-7. In some examples, the process 800 may be carried out by any suitable apparatus or means for carrying out the functions or algorithm described below.

At block 802, the apparatus may receive a single-ended signal at either: a first low noise amplifier input of a first LNA, or a second LNA input of a second LNA. For example, the communication and processing circuitry 741, as shown and described in connection with FIG. 7, may provide a means for receiving a single-ended signal at either: a first low noise amplifier input of a first LNA, or a second LNA input of a second LNA. According to some aspects, the single-ended signal may be received from an external LNA coupled to the second LNA input. According to such aspects, the first LNA and the second LNA may be a first plurality of LNAs and a second plurality of LNAs, respectively, each of the first plurality of LNAs and the second plurality of LNAs having a corresponding plurality of distinct gains. Still further according to such aspects, the apparatus may select one of the first plurality of LNAs to be the first LNA and turn off all other ones of the first plurality of LNAs or select one of the second plurality of LNAs to be the second LNA and turn off all other ones of the second plurality of LNAs. For example, the LNA state circuitry, as shown and described in connection with FIG. 7, may provide a means for selecting one of the first plurality of LNAs to be the first LNA and turning off all other ones of the first plurality of LNAs, or selecting one of the second plurality of LNAs to be the second LNA and turning off all other ones of the second plurality of LNAs.

In response to the single-ended signal being received at the first LNA, the process 800 proceeds to block 804.

At block 804, the apparatus may turn on the first LNA, close a first switch coupling a first LNA output of the first LNA to a first inductor node of a load inductor, turn off the second LNA, and open a second switch coupling a second LNA output of the second LNA to a second inductor node of the load inductor. For example, the switch state circuitry, as shown and described in connection with FIG. 7, may provide a means for turning on the first LNA, closing a first switch coupling a first LNA output of the first LNA to a first inductor node of a load inductor, turning off the second LNA, and opening a second switch coupling a second LNA output of the second LNA to a second inductor node of the load. From block 804, the process continues to block 806.

Block 806 may be optional. If included, at block 806, the apparatus may configure a first series combination of the second switch and the second LNA as a first load to the second inductor node in response to the receiving the single-ended signal at the first LNA input. For example, the LNA state circuitry, as shown and described in connection with FIG. 7, may provide a means for configuring a first series combination of the second switch and the second LNA as a first load to the second inductor node in response to the receiving the single-ended signal at the first LNA input. In some examples, the apparatus may also configure a respective impedance of the first load and the second load to be equivalent to a series combination of a resistor and a capacitor.

Returning to block 802, in response to the single-ended signal being received at the second LNA, the process 800 proceeds to block 808.

At block 808, the apparatus may turn off the first LNA, open the first switch, turn on the second LNA, and close the second switch. For example, the switch state circuitry, as shown and described in connection with FIG. 7, may provide a means for turning off the first LNA, opening the first switch, turning on the second LNA, and closing the second switch. From block 808, the process continues to block 810.

Block 810 may be optional. If included, at block 810, the apparatus may configure a second series combination of the first switch and the first LNA as a second load to the first inductor node in response to the receiving the single-ended signal at the second LNA input. For example, the LNA state circuitry, as shown and described in connection with FIG. 7, may provide a means for configuring a second series combination of the first switch and the first LNA as a second load to the first inductor node in response to the receiving the single-ended signal at the second LNA input.

Following blocks 806 and 810 (or blocks 804 and 808 if blocks 806 and 810 are not included), the process proceeds to block 812.

At block 812, the apparatus may transform the received single-ended signal to an amplified differential output signal across the first inductor node and the second inductor node. For example, the communications and processing circuitry 741, as shown and described in connection with FIG. 7, may provide a means for transforming the received single-ended signal to an amplified differential output signal across the first inductor node and the second inductor node. Thereafter, the process 800 may end.

In accordance with various aspects of the disclosure, an clement, or any portion of an element, or any combination of elements may be implemented with a processing system 701 that includes one or more processors, generally represented by processor 704. The one or more processors (generally represented by processor 704), as utilized in the apparatus 700, may be configured to, individually or collectively, implement any one or more of the methods or processes described herein and/or illustrated, for example, in FIGS. 1-8.

Of course, in the above examples, the circuitry included in the one or more processors (generally represented by processor 704) of FIG. 7 is merely provided as an example. Other means for carrying out the described processes or functions may be included within various aspects of the present disclosure, including but not limited to the instructions stored in the computer-readable medium 706 of FIG. 7 or any other suitable apparatus or means described in association with any one of the FIGS. 1-7 utilizing, for example, the processes and/or algorithms described herein in relation to any of the preceding figures and/or FIG. 8.

The following provides an overview of aspects of the present disclosure:
Aspect 1: An apparatus, comprising: a load inductor having a first inductor node at a first end, a second inductor node at a second end, and a center inductor node between the first end and the second end; a first switch having a first terminal and a selectively opened or closed second terminal, the first terminal coupled to the first inductor node; a second switch having a third terminal and a selectively opened or closed fourth terminal, the third terminal coupled to the second inductor node; a first low noise amplifier (LNA) having a first LNA input and a first LNA output, the first LNA output coupled to the selectively opened or closed second terminal of the first switch; and a second LNA having a second LNA input and a second LNA output, the second LNA output coupled to the selectively opened or closed fourth terminal of the second switch.
Aspect 2: The apparatus of aspect 1, further comprising: a first load, configured as a first series combination of the second switch in an open state and the second LNA in an off state, coupled to the second inductor node, or a second load, configured as a second series combination of the first switch in the open state and the first LNA in the off state, coupled to the first inductor node.
Aspect 3: The apparatus of aspect 1 or aspect 2, wherein the first load is coupled to the second inductor node in response to the apparatus being configured to transform a single-ended input at the first LNA input to an amplified differential output across the first inductor node and the second inductor node, or the second load is coupled to the first inductor node in response to the apparatus being configured to transform the single-ended input at the second LNA input to the amplified differential output across the first inductor node and the second inductor node.
Aspect 4: The apparatus of any of aspects 1 through 3, wherein a respective impedance of the first load and the second load is equivalent to a series combination of a resistor and a capacitor.
Aspect 5: The apparatus of any of aspects 1 through 4, further comprising: a power amplifier having a power amplifier output coupled to the first LNA input via a power amplifier balun; and an internal transmit/receive switch coupled in parallel between the power amplifier balun and the first LNA input.
Aspect 6: The apparatus of any of aspects 1 through 5, wherein the load inductor, the first switch, the second switch, the first LNA, and the second LNA are components of a radio frequency front end (RFFE), and the apparatus further comprises: an external LNA (xLNA) having an xLNA input and an xLNA output, the xLNA separate from the RFFE, the xLNA output coupled to the second LNA input.
Aspect 7: The apparatus of claim 6, wherein the RFFE further comprises: a power amplifier having a power amplifier output coupled to the first LNA input via a power amplifier balun; and an internal transmit/receive switch coupled in parallel between the power amplifier balun and the first LNA input, wherein: in an internal LNA (iLNA) configuration: an antenna couples to the power amplifier balun, and in an xLNA configuration: the antenna couples to an antenna port of an antenna multiplexer switch, separate from the RFFE and different from the internal transmit/receive switch, an output of the antenna multiplexer switch couples to the xLNA input, and an input of the antenna multiplexer switch couples to the power amplifier balun.
Aspect 8: The apparatus of any of aspects 1 through 7, wherein a polarity of the first inductor node relative to the center inductor node is opposite to the polarity of the second inductor node relative to the center inductor node.
Aspect 9: The apparatus of any of aspects 1 through 8, wherein the first switch and the second switch are configured as respective single-pole-single-throw switches.
Aspect 10: The apparatus of any of aspects 1 through 9, wherein the first switch, the second switch, the first LNA, and the second LNA are fabricated as a single core circuit.
Aspect 11: The apparatus of aspect 10, further comprising: respective input matching networks coupled to the first LNA and the second LNA are included in the single core circuit.
Aspect 12: The apparatus of any of aspects 1 through 11, wherein the first LNA and the second LNA are duplicates.
Aspect 13: The apparatus of any of aspects 1 through 12, wherein: the first LNA comprises: a first transconductance low noise amplifier transistor coupled in series with a first cascode transistor; and the second LNA comprises a second transconductance transistor coupled in series with a second cascode transistor.
Aspect 14: The apparatus of any of aspects 1 through 13, wherein each of the first LNA and the second LNA are respectively comprised of: a first n-channel metal-oxide semiconductor (NMOS) transistor having a first drain, a first gate, and a first source configured as a transconductance amplifier; and a second NMOS transistor having a second drain, a second gate, and a second source configured as a cascode amplifier, wherein: the first gate corresponds to the first LNA input and the second LNA input, respectively, the first source is coupled to ground, the first drain is coupled to the second source, the second drain corresponds to the first LNA output and the second LNA output, respectively, a first direct current (DC) voltage bias is coupled to the first gate, and a second DC voltage bias is coupled to the second gate.
Aspect 15: The apparatus of aspect 14, wherein the first source is coupled to ground via a source inductor.
Aspect 16: The apparatus of any of aspects 1 through 15, further comprising an external LNA coupled to the second LNA input.
Aspect 17: The apparatus of any of aspects 1 through 16, wherein the first LNA and the second LNA are a first plurality of LNAs and a second plurality of LNAs, respectively, each of the first plurality of LNAs and the second plurality of LNAs having a corresponding plurality of distinct gains, and the apparatus is further configured to: select one of the first plurality of LNAs to be the first LNA and turn off all other ones of the first plurality of LNAs, or select one of the second plurality of LNAs to be the second LNA and turn off all other ones of the second plurality of LNAs.
Aspect 18: A method operational at an apparatus, comprising: receiving a single-ended signal at either: a first low noise amplifier (LNA) input of a first LNA, or a second LNA input of a second LNA; either: turning on the first LNA, closing a first switch coupling a first LNA output of the first LNA to a first inductor node of a load inductor, turning off the second LNA, and opening a second switch coupling a second LNA output of the second LNA to a second inductor node of the load inductor in response to the receiving the single-ended signal at the first LNA input, or turning off the first LNA, opening the first switch, turning on the second LNA, and closing the second switch, in response to the receiving the single-ended signal at the second LNA input; and transforming the received single-ended signal to an amplified differential output signal across the first inductor node and the second inductor node.
Aspect 19: The method of aspect 18, further comprising: configuring a first series combination of the second switch and the second LNA as a first load to the second inductor node in response to the receiving the single-ended signal at the first LNA input, or configuring a second series combination of the first switch and the first LNA as a second load to the first inductor node in response to the receiving the single-ended signal at the second LNA input.
Aspect 20: The method of aspect 18 or aspect 19, further comprising: configuring a respective impedance of the first load and the second load to be equivalent to a series combination of a resistor and a capacitor.
Aspect 21: The method of any of aspects 18 through 20, wherein the apparatus further comprises: a power amplifier having a power amplifier output coupled to the first LNA input via a power amplifier balun; and an internal transmit/receive switch coupled in parallel between the power amplifier balun and the first LNA input.
Aspect 22: The method of any of aspects 18 through 21, wherein: the first LNA comprises: a first transconductance low noise amplifier transistor coupled in series with a first cascode transistor; and the second LNA comprises a second transconductance transistor coupled in series with a second cascode transistor.
Aspect 23: The method of any of aspects 18 through 22, further comprising respectively configuring each of the first LNA and the second LNA as: a first n-channel metal-oxide semiconductor (NMOS) transistor having a first drain, a first gate, and a first source configured as a transconductance amplifier; and a second NMOS transistor having a second drain, a second gate, and a second source configured as a cascode amplifier, wherein: the first gate corresponds to the first LNA input and the second LNA input, respectively, the first source is coupled to ground, the first drain is coupled to the second source, the second drain corresponds to the first LNA output and the second LNA output, respectively, and the method further comprises: providing a first direct current (DC) voltage bias to the first gate, and providing a second DC voltage bias to the second gate to turn on the transconductance amplifier and the cascode amplifier, respectively.
Aspect 24: The method of aspect 23, wherein the first source is coupled to ground via a source inductor.
Aspect 25: The method of any of aspects 18 through 24, further comprising receiving the single-ended signal from an external LNA coupled to the second LNA input.
Aspect 26: The method of any of aspects 18 through 25, wherein the first LNA and the second LNA are a first plurality of LNAs and a second plurality of LNAs, respectively, each of the first plurality of LNAs and the second plurality of LNAs having a corresponding plurality of distinct gains, and the method further comprises: selecting one of the first plurality of LNAs to be the first LNA and turning off all other ones of the first plurality of LNAs, or selecting one of the second plurality of LNAs to be the second LNA and turning off all other ones of the second plurality of LNAs.
Aspect 27: An apparatus, comprising: one or more memories; and one or more processors being configured to, individually or collectively, based at least in part on information stored in the one or more memories: receive a single-ended signal at either: a first low noise amplifier (LNA) input of a first LNA, or a second LNA input of a second LNA; either: turn on the first LNA, close a first switch coupling a first LNA output of the first LNA to a first inductor node of a load inductor, turn off the second LNA, and open a second switch coupling a second LNA output of the second LNA to a second inductor node of the load inductor in response to the receiving the single-ended signal at the first LNA input, or turn off the first LNA, open the first switch, turn on the second LNA, and close the second switch, in response to the receiving the single-ended signal at the second LNA input; and transform the received single-ended signal to an amplified differential output signal across the first inductor node and the second inductor node.
Aspect 28: The apparatus of aspect 27, wherein the one or more processors are further configured to: configure a first series combination of the second switch and the second LNA as a first load to the second inductor node in response to the receiving the single-ended signal at the first LNA input, or configure a second series combination of the first switch and the first LNA as a second load to the first inductor node in response to the receiving the single-ended signal at the second LNA input.
Aspect 29: The apparatus of aspect 27 or aspect 28, wherein the one or more processors are further configured to: configure a respective impedance of the first load and the second load to be equivalent to a series combination of a resistor and a capacitor.
Aspect 30: The apparatus of any of aspects 27 through 29, further comprising: a power amplifier having a power amplifier output coupled to the first LNA input via a power amplifier balun; and an internal transmit/receive switch coupled in parallel between the power amplifier balun and the first LNA input.
Aspect 31: The apparatus of any of aspects 27 through 30, wherein: the first LNA comprises: a first transconductance low noise amplifier transistor coupled in series with a first cascode transistor; and the second LNA comprises a second transconductance transistor coupled in series with a second cascode transistor.
Aspect 32: The apparatus of any of aspects 27 through 31, wherein the one or more processors are further configured to respectively configure each of the first LNA and the second LNA as: a first n-channel metal-oxide semiconductor (NMOS) transistor having a first drain, a first gate, and a first source configured as a transconductance amplifier; and a second NMOS transistor having a second drain, a second gate, and a second source configured as a cascode amplifier, wherein: the first gate corresponds to the first LNA input and the second LNA input, respectively, the first source is coupled to ground, the first drain is coupled to the second source, the second drain corresponds to the first LNA output and the second LNA output, respectively, and the one or more processors are further configured to: provide a first direct current (DC) voltage bias to the first gate, and provide a second DC voltage bias to the second gate to turn on the transconductance amplifier and the cascode amplifier, respectively.
Aspect 33: The apparatus of aspect 32, wherein the first source is coupled to ground via a source inductor.
Aspect 34: The apparatus of any of aspects 27 through 33, wherein the one or more processors are further configured to receive the single-ended signal from an external LNA coupled to the second LNA input.
Aspect 35: The apparatus of any of aspects 27 through 34, wherein the first LNA and the second LNA are a first plurality of LNAs and a second plurality of LNAs, respectively, each of the first plurality of LNAs and the second plurality of LNAs having a corresponding plurality of distinct gains, and the one or more processors are further configured to: select one of the first plurality of LNAs to be the first LNA and turn off all other ones of the first plurality of LNAs, or select one of the second plurality of LNAs to be the second LNA and turn off all other ones of the second plurality of LNAs.
Aspect 36: An apparatus, comprising: means for receiving a single-ended signal at either: a first low noise amplifier (LNA) input of a first LNA, or a second LNA input of a second LNA; means for either: turning on the first LNA, closing a first switch coupling a first LNA output of the first LNA to a first inductor node of a load inductor, turning off the second LNA, and opening a second switch coupling a second LNA output of the second LNA to a second inductor node of the load inductor in response to the receiving the single-ended signal at the first LNA input, or turning off the first LNA, opening the first switch, turning on the second LNA, and closing the second switch, in response to the receiving the single-ended signal at the second LNA input; and means for transforming the received single-ended signal to an amplified differential output signal across the first inductor node and the second inductor node.
Aspect 37: The apparatus of aspect 36, further comprising: means for configuring a first series combination of the second switch and the second LNA as a first load to the second inductor node in response to the receiving the single-ended signal at the first LNA input, or means for configuring a second series combination of the first switch and the first LNA as a second load to the first inductor node in response to the receiving the single-ended signal at the second LNA input.
Aspect 38: The apparatus of aspect 36 or aspect 37, further comprising: means for configuring a respective impedance of the first load and the second load to be equivalent to a series combination of a resistor and a capacitor.
Aspect 39: The apparatus of any of aspects 36 through 38, further comprising: a power amplifier having a power amplifier output coupled to the first LNA input via a power amplifier balun; and an internal transmit/receive switch coupled in parallel between the power amplifier balun and the first LNA input.
Aspect 40: The apparatus of any of aspects 36 through 39, wherein the first LNA comprises a first transconductance low noise amplifier transistor coupled in series with a first cascode transistor; and the second LNA comprises a second transconductance transistor coupled in series with a second cascode transistor.
Aspect 41: The apparatus of any of aspects 36 through 40, further comprising means for respectively configuring each of the first LNA and the second LNA as: a first n-channel metal-oxide semiconductor (NMOS) transistor having a first drain, a first gate, and a first source configured as a transconductance amplifier; and a second NMOS transistor having a second drain, a second gate, and a second source configured as a cascode amplifier, wherein: the first gate corresponds to the first LNA input and the second LNA input, respectively, the first source is coupled to ground, the first drain is coupled to the second source, the second drain corresponds to the first LNA output and the second LNA output, respectively, and the apparatus further comprises: means for providing a first direct current (DC) voltage bias to the first gate, and means for providing a second DC voltage bias to the second gate to turn on the transconductance amplifier and the cascode amplifier, respectively.
Aspect 42: The apparatus of aspect 41, wherein the first source is coupled to ground via a source inductor.
Aspect 43: The apparatus of any of aspects 36 through 42, further comprising means for receiving the single-ended signal from an external LNA coupled to the second LNA input.
Aspect 44: The apparatus of any of aspects 36 through 43, wherein the first LNA and the second LNA are a first plurality of LNAs and a second plurality of LNAs, respectively, each of the first plurality of LNAs and the second plurality of LNAs having a corresponding plurality of distinct gains, and the apparatus further comprises: means for selecting one of the first plurality of LNAs to be the first LNA and turning off all other ones of the first plurality of LNAs, or means for selecting one of the second plurality of LNAs to be the second LNA and turning off all other ones of the second plurality of LNAs.
Aspect 45: A non-transitory computer-readable medium storing instructions that when executed by a processing circuit having one or more processors causes the one or more processors, individually or collectively, to: receive a single-ended signal at either: a first low noise amplifier (LNA) input of a first LNA, or a second LNA input of a second LNA; either: turn on the first LNA, close a first switch coupling a first LNA output of the first LNA to a first inductor node of a load inductor, turn off the second LNA, and open a second switch coupling a second LNA output of the second LNA to a second inductor node of the load inductor in response to the receiving the single-ended signal at the first LNA input, or turn off the first LNA, open the first switch, turn on the second LNA, and close the second switch, in response to the receiving the single-ended signal at the second LNA input; and transform the received single-ended signal to an amplified differential output signal across the first inductor node and the second inductor node.
Aspect 46: The non-transitory computer-readable medium of aspect 45, wherein the instructions further cause the one or more processors, individually or collectively, to: configure a first series combination of the second switch and the second LNA as a first load to the second inductor node in response to the receiving the single-ended signal at the first LNA input, or configure a second series combination of the first switch and the first LNA as a second load to the first inductor node in response to the receiving the single-ended signal at the second LNA input.
Aspect 47: The non-transitory computer-readable medium of aspect 45 or aspect 46, wherein the instructions further cause the one or more processors, individually or collectively, to: configure a respective impedance of the first load and the second load to be equivalent to a series combination of a resistor and a capacitor.
Aspect 48: The non-transitory computer-readable medium of any of aspects 45 through 47, wherein the instructions further cause the one or more processors, individually or collectively, to: transmit a power amplifier having a power amplifier output coupled to the first LNA input via a power amplifier balun; and close, prior to the transmit, an internal transmit/receive switch coupled in parallel between the power amplifier balun and the first LNA input.
Aspect 49: The non-transitory computer-readable medium of any of aspects 45 through 48, wherein: the first LNA comprises: a first transconductance low noise amplifier transistor coupled in series with a first cascode transistor; and the second LNA comprises a second transconductance transistor coupled in series with a second cascode transistor.
Aspect 50: The non-transitory computer-readable medium of any of aspects 45 through 49, wherein the instructions further cause the one or more processors, individually or collectively, to respectively configure each of the first LNA and the second LNA as: a first n-channel metal-oxide semiconductor (NMOS) transistor having a first drain, a first gate, and a first source configured as a transconductance amplifier; and a second NMOS transistor having a second drain, a second gate, and a second source configured as a cascode amplifier, wherein: the first gate corresponds to the first LNA input and the second LNA input, respectively, the first source is coupled to ground, the first drain is coupled to the second source, the second drain corresponds to the first LNA output and the second LNA output, respectively, and the instructions further cause the one or more processors, individually or collectively, to: provide a first direct current (DC) voltage bias to the first gate, and provide a second DC voltage bias to the second gate to turn on the transconductance amplifier and the cascode amplifier, respectively.
Aspect 51: The non-transitory computer-readable medium of aspect 50, wherein the first source is coupled to ground via a source inductor.
Aspect 52: The non-transitory computer-readable medium of any of aspects 45 through 51, wherein the instructions further cause the one or more processors, individually or collectively, to receive the single-ended signal from an external LNA coupled to the second LNA input.
Aspect 53: The non-transitory computer-readable medium of any of aspects 45 through 52, wherein the first LNA and the second LNA are a first plurality of LNAs and a second plurality of LNAs, respectively, each of the first plurality of LNAs and the second plurality of LNAs having a corresponding plurality of distinct gains, and the instructions further cause the one or more processors, individually or collectively, to: select one of the first plurality of LNAs to be the first LNA and turn off all other ones of the first plurality of LNAs, or select one of the second plurality of LNAs to be the second LNA and turn off all other ones of the second plurality of LNAs.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

Several aspects of a wireless communication network have been presented with reference to an exemplary implementation. As those skilled in the art will readily appreciate, various aspects described throughout this disclosure may be extended to other telecommunication systems, network architectures and communication standards.

By way of example, various aspects may be implemented within other systems defined by 3GPP, such as Long-Term Evolution (LTE), the Evolved Packet System (EPS), the Universal Mobile Telecommunication System (UMTS), and/or the Global System for Mobile (GSM). Various aspects may also be extended to systems defined by the 3rd Generation Partnership Project 2 (3GPP2), such as CDMA 2000 and/or Evolution-Data Optimized (EV-DO). Other examples may be implemented within systems employing IEEE 802.11 (Wi-Fi), IEEE 802.16 (WiMAX), IEEE 802.20, Ultra-Wideband (UWB), Bluetooth, and/or other suitable systems. The actual telecommunication standard, network architecture, and/or communication standard employed will depend on the specific application and the overall design constraints imposed on the system.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, configuration, or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features, and/or functions illustrated in FIGS. 1-8 may be rearranged and/or combined into a single component, step, feature, or function or embodied in several components, steps, or functions. Additional elements, components, steps, and/or functions may also be added without departing from novel features disclosed herein. The apparatus, devices, and/or components illustrated in FIGS. 1-8 may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order and are not meant to be limited to the specific order or hierarchy presented unless specifically recited therein. While some examples illustrated herein depict only time and frequency domains, additional domains such as a spatial domain are also contemplated in this disclosure.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” The use of the singular form herein may be understood to include the plural, and vice versa. Unless specifically stated otherwise, the term “some” refers to one or more.

The word “obtain” as used herein may mean, for example, acquire, calculate, construct, derive, determine, receive, and/or retrieve. The preceding list is exemplary and not limiting. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

As used herein, the term “determine” or “determining” encompasses a wide variety of actions and, therefore, “determining” can include calculating, computing, processing, deriving, investigating, looking up (such as via looking up in a table, a database, or another data structure), inferring, ascertaining, measuring, and the like. Also, “determining” can include receiving (such as receiving information), accessing (such as accessing data stored in memory), transmitting (such as transmitting information) and the like. Also, “determining” can include resolving, selecting, obtaining, choosing, establishing, and other similar actions.

As used herein, a phrase referring to “at least one of” a list of items refers to any combination of those items, including single members. As an example, “at least one of: a, b, or c” is intended to cover: a, b, c, a-b, a-c, b-c, and a-b-c. As used herein, “or” is intended to be interpreted in the inclusive sense, unless otherwise explicitly indicated. For example, “a or b” may include a only, b only, or a combination of a and b. Similarly, a phrase referring to A and/or B may include A only, B only, or a combination of A and B.

As used herein, “based on” is intended to be interpreted in the inclusive sense, unless otherwise explicitly indicated. For example, “based on” may be used interchangeably with “based at least in part on,” “associated with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The various illustrative components, logic, logical blocks, modules, circuits, operations, and algorithm processes described in connection with the examples disclosed herein may be implemented as electronic hardware, firmware, software, or combinations of hardware, firmware, or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

Various modifications to the examples described in this disclosure may be readily apparent to persons having ordinary skill in the art, and the generic principles defined herein may be applied to other examples without departing from the spirit or scope of this disclosure. Thus, the claims are not intended to be limited to the examples shown herein, but are to be accorded the widest scope consistent with this disclosure, the principles and the novel features disclosed herein.

Additionally, various features described in this specification in the context of separate examples can also be implemented in combination in a single implementation. Conversely, various features described in the context of a single implementation can also be implemented in multiple examples separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the examples described above should not be understood as requiring such separation in all examples, and it should be understood that the described program components and systems can generally be integrated together in a single software product or packaged into multiple software products.

What is claimed:

1. An apparatus, comprising:
a load inductor having a first inductor node at a first end, a second inductor node at a second end, and a center inductor node between the first end and the second end;
a first switch having a first terminal and a selectively opened or closed second terminal, the first terminal coupled to the first inductor node;
a second switch having a third terminal and a selectively opened or closed fourth terminal, the third terminal coupled to the second inductor node;
a first low noise amplifier (LNA) having a first LNA input and a first LNA output, the first LNA output coupled to the selectively opened or closed second terminal of the first switch; and
a second LNA having a second LNA input and a second LNA output, the second LNA output coupled to the selectively opened or closed fourth terminal of the second switch.

2. The apparatus of claim 1, further comprising at least one of:
a first load, configured as a first series combination of the second switch in an open state and the second LNA in an off state, coupled to the second inductor node, or
a second load, configured as a second series combination of the first switch in the open state and the first LNA in the off state, coupled to the first inductor node.

3. The apparatus of claim 2, wherein at least one of:
the first load is coupled to the second inductor node in response to the apparatus being configured to transform a single-ended input at the first LNA input to an amplified differential output across the first inductor node and the second inductor node, or
the second load is coupled to the first inductor node in response to the apparatus being configured to transform the single-ended input at the second LNA input to the amplified differential output across the first inductor node and the second inductor node.

4. The apparatus of claim 1, further comprising:
a power amplifier having a power amplifier output coupled to the first LNA input via a power amplifier balun; and
an internal transmit/receive switch coupled in parallel between the power amplifier balun and the first LNA input.

5. The apparatus of claim 1, wherein the load inductor, the first switch, the second switch, the first LNA, and the second LNA are components of a radio frequency front end (RFFE), and the apparatus further comprises:
an external LNA (xLNA) having an xLNA input and an xLNA output, the xLNA separate from the RFFE, the xLNA output coupled to the second LNA input.

6. The apparatus of claim 5, wherein the RFFE further comprises:
a power amplifier having a power amplifier output coupled to the first LNA input via a power amplifier balun; and
an internal transmit/receive switch coupled in parallel between the power amplifier balun and the first LNA input, wherein:
in an internal LNA (iLNA) configuration:
an antenna couples to the power amplifier balun, and
in an xLNA configuration:
the antenna couples to an antenna port of an antenna multiplexer switch, separate from the RFFE and different from the internal transmit/receive switch,
an output of the antenna multiplexer switch couples to the xLNA input, and
an input of the antenna multiplexer switch couples to the power amplifier balun.

7. The apparatus of claim 1, wherein a polarity of the first inductor node relative to the center inductor node is opposite to the polarity of the second inductor node relative to the center inductor node.

8. The apparatus of claim 1, wherein the first switch, the second switch, the first LNA, and the second LNA are fabricated as a single core circuit.

9. The apparatus of claim 1, wherein the first LNA and the second LNA are duplicates.

10. The apparatus of claim 1, wherein the first LNA and the second LNA are a first plurality of LNAs and a second plurality of LNAs, respectively, each of the first plurality of LNAs and the second plurality of LNAs having a corresponding plurality of distinct gains, and the apparatus is further configured to at least one of:
select one of the first plurality of LNAs to be the first LNA and turn off all other ones of the first plurality of LNAs, or
select one of the second plurality of LNAs to be the second LNA and turn off all other ones of the second plurality of LNAs.

11. A method at an apparatus, comprising:
receiving a single-ended signal at either:
a first low noise amplifier (LNA) input of a first LNA, or
a second LNA input of a second LNA;
either:
turning on the first LNA, closing a first switch coupling a first LNA output of the first LNA to a first inductor node of a load inductor, turning off the second LNA, and opening a second switch coupling a second LNA output of the second LNA to a second inductor node of the load inductor in response to the receiving the single-ended signal at the first LNA input, or
turning off the first LNA, opening the first switch, turning on the second LNA, and closing the second switch, in response to the receiving the single-ended signal at the second LNA input; and
transforming the received single-ended signal to an amplified differential output signal across the first inductor node and the second inductor node.

12. The method of claim 11, further comprising:
configuring a first series combination of the second switch and the second LNA as a first load to the second inductor node in response to the receiving the single-ended signal at the first LNA input, or
configuring a second series combination of the first switch and the first LNA as a second load to the first inductor node in response to the receiving the single-ended signal at the second LNA input.

13. The method of claim 11, wherein the apparatus further comprises:
a power amplifier having a power amplifier output coupled to the first LNA input via a power amplifier balun; and
an internal transmit/receive switch coupled in parallel between the power amplifier balun and the first LNA input.

14. The method of claim 11, further comprising receiving the single-ended signal from an external LNA coupled to the second LNA input.

15. The method of claim 11, wherein the first LNA and the second LNA are a first plurality of LNAs and a second plurality of LNAs, respectively, each of the first plurality of LNAs and the second plurality of LNAs having a corresponding plurality of distinct gains, and the method further comprises:
selecting one of the first plurality of LNAs to be the first LNA and turning off all other ones of the first plurality of LNAs, or
selecting one of the second plurality of LNAs to be the second LNA and turning off all other ones of the second plurality of LNAs.

16. An apparatus, comprising:
one or more memories; and
one or more processors being configured to, individually or collectively, based at least in part on information stored in the one or more memories:
receive a single-ended signal at either:
a first low noise amplifier (LNA) input of a first LNA, or
a second LNA input of a second LNA;
either:
turn on the first LNA, close a first switch coupling a first LNA output of the first LNA to a first inductor node of a load inductor, turn off the second LNA, and open a second switch coupling a second LNA output of the second LNA to a second inductor node of the load inductor in response to the receiving the single-ended signal at the first LNA input, or
turn off the first LNA, open the first switch, turn on the second LNA, and close the second switch, in response to the receiving the single-ended signal at the second LNA input; and
transform the received single-ended signal to an amplified differential output signal across the first inductor node and the second inductor node.

17. The apparatus of claim 16, wherein the one or more processors are further configured to:
configure a first series combination of the second switch and the second LNA as a first load to the second inductor node in response to the receiving the single-ended signal at the first LNA input, or
configure a second series combination of the first switch and the first LNA as a second load to the first inductor node in response to the receiving the single-ended signal at the second LNA input.

18. The apparatus of claim 16, further comprising:
a power amplifier having a power amplifier output coupled to the first LNA input via a power amplifier balun; and
an internal transmit/receive switch coupled in parallel between the power amplifier balun and the first LNA input.

19. The apparatus of claim 16, wherein the one or more processors are further configured to receive the single-ended signal from an external LNA coupled to the second LNA input.

20. The apparatus of claim 16, wherein the first LNA and the second LNA are a first plurality of LNAs and a second plurality of LNAs, respectively, each of the first plurality of LNAs and the second plurality of LNAs having a corresponding plurality of distinct gains, and the one or more processors are further configured to:
select one of the first plurality of LNAs to be the first LNA and turn off all other ones of the first plurality of LNAs, or
select one of the second plurality of LNAs to be the second LNA and turn off all other ones of the second plurality of LNAs.
